(19) United States
(12) Patent Application Publication
(10) Pub. No.: US 2024/0355650 A1
(43) Pub. Date: Oct. 24, 2024

(54) DRY DEVELOPMENT APPARATUS AND METHODS FOR VOLATILIZATION OF DRY DEVELOPMENT BYPRODUCTS IN WAFERS

(71) Applicant: Lam Research Corporation, Fremont, CA (US)

(72) Inventors: Sivananda Krishnan Kanakasabapathy, Pleasanton, CA (US); Jerome S. Hubacek, Fremont, CA (US); Daniel Peter, Sunnyvale, CA (US); Samantha S.H. Tan, Newark, CA (US)

(21) Appl. No.: 18/569,213

(22) PCT Filed: Jun. 14, 2022
(86) PCT No.: PCT/US2022/033488

§ 371 Date: Dec. 11, 2023

Related U.S. Application Data
(60) Provisional application No. 63/202,536, filed on Jun. 15, 2021.

(51) Int. Cl. H01L 21/67; H01L 21/687

(52) U.S. Cl. CPC H01L 21/67115; H01L 21/67109; H01L 21/67248; H01L 21/68742

(57) ABSTRACT

Disclosed herein are radiative heating systems and methods for use with dry development processes. Such systems and methods may, in some instances, allow for volatile halides that may be trapped on the surface of a wafer after dry development processing has completed to be driven out of the wafer through radiative heating thereof. Such systems and methods may, in some instances, be provided in an in-situ context in which the wafers being heated are radiatively heated within the same chamber as the dry development process is performed. In other contexts, such radiative heating may be performed in other locations, e.g., as the wafer transits from the processing chamber to another chamber or in another chamber entirely.

### RELATED APPLICATION(S)

A PCT Request Form is filed concurrently with this specification as part of the present application. Each application that the present application claims benefit of or priority to as identified in the concurrently filed PCT Request Form is incorporated by reference herein in its entirety and for all purposes.

### BACKGROUND

The fabrication of semiconductor devices, such as integrated circuits, is a multi-step process involving photolithography. In general, the process includes the deposition of material on a wafer and patterning the material through lithographic techniques to form structural features (e.g., transistors and circuitry) of the semiconductor device. The steps of a typical photolithography process known in the art include: preparing the substrate; applying a photoresist, such as by spin coating; exposing the photoresist to light in a desired pattern, causing the exposed areas of the photoresist to become more or less soluble in a developer solution; developing by applying the developer solution to remove either the exposed or the unexposed areas of the photoresist; and subsequent processing to create features on the areas of the substrate from which the photoresist has been removed, such as by etching or material deposition.

The evolution of semiconductor design has created the need, and has been driven by the ability, to create ever smaller features on semiconductor substrate materials. This progression of technology has been characterized in “Moore's Law” as a doubling of the density of transistors in dense integrated circuits every two years. Indeed, chip design and manufacturing has progressed such that modem microprocessors may contain billions of transistors and other circuit features on a single chip. Individual features on such chips may be on the order of 22 nanometers (nm) or smaller, in some cases less than 10 nm.

One challenge in manufacturing devices having such small features is the ability to reliably and reproducibly create photolithographic masks having sufficient resolution. Current photolithography processes typically use 193 nm ultraviolet (UV) light to expose a photoresist. The fact that the light has a wavelength significantly greater than the desired size of the features to be produced on the semiconductor substrate creates inherent issues. Achieving feature sizes smaller than the wavelength of the light requires use of complex resolution enhancement techniques, such as multi-patterning. Thus, there is significant interest and research effort in developing photolithographic techniques using shorter wavelength light, such as extreme ultraviolet radiation (EUV), having a wavelength of from 10 nm to 15 nm, e.g., 13.5 nm.

EUV photolithographic processes can present challenges, however, including low power output and loss of light during patterning. Organic chemically amplified resists (CAR) similar to those used in 193 nm UV lithography have potential drawbacks when used in EUV lithography, particularly as they have low absorption coefficients in the EUV spectrum and the diffusion of photo-activated chemical species can result in pattern blur or line edge roughness. Furthermore, in order to provide the etch resistance required to pattern underlying device layers, increased thicknesses of CARs may need to be used, making small features patterned in conventional CAR materials have high aspect ratios that are at risk of pattern collapse. Accordingly, there remains a need for improved EUV photoresist materials having such properties as decreased thickness, greater absorbance, and greater etch resistance.

The background description provided herein is for the purpose of generally presenting the context of the present technology. Work of the presently named inventors, to the extent it is described in this background section, as well as aspects of the description that may not otherwise qualify as prior art at the time of filing, are neither expressly nor impliedly admitted as prior art against the present technology.

### SUMMARY

Details of one or more implementations of the subject matter described in this specification are set forth in the accompanying drawings and the description below. Other features, aspects, and advantages will become apparent from the description, the drawings, and the claims.

In some implementations, an apparatus may be provided that includes a processing chamber, a pedestal located within the processing chamber and having a wafer support surface configured to support a wafer during dry development processing of the wafer within the processing chamber, a pedestal cooling system configured to cool at least the wafer support surface of the pedestal, one or more light sources positioned so as to direct light at a location within the processing chamber and on or above the pedestal, and a gas distribution system with one or more inlets and a plurality of outlets, the gas distribution system configured to direct gas flowed therethrough out of the outlets into a region above the wafer support surface of the pedestal.

In some implementations of the apparatus, at least one of the one or more light sources may be configured to emit light predominantly in the blue spectrum of wavelengths between 400 nm to 490 nm, light predominantly in the infrared spectrum of wavelengths between 800 nm to 1300 nm, or light predominantly in the blue and infrared spectrums of wavelengths between 400 nm to 490 nm and 800 nm to 1300 nm, respectively.

In some implementations of the apparatus, at least one of the one or more light sources may be configured to emit light predominantly in the blue spectrum of wavelengths between 400 nm to 490 nm.

In some implementations of the apparatus, at least one of the one or more light sources may be configured to emit light predominantly in the infrared spectrum of wavelengths between 800 nm to 1300 nm.

In some implementations of the apparatus, there may be a plurality of light sources and at least a majority of the light sources may be configured to emit light predominantly in the blue spectrum of wavelengths between 400 nm to 490 nm, light predominantly in the infrared spectrum of wavelengths between 800 nm to 1300 nm, or light predominantly in the blue and infrared spectrums of wavelengths between 400 nm to 490 nm and 800 nm to 1300 nm, respectively.

In some implementations of the apparatus, there may be a plurality of light sources and at least a majority of the light sources may be configured to emit light predominantly in the blue spectrum of wavelengths between 400 nm to 490 nm.

In some implementations of the apparatus, there may be a plurality of light sources and at least a majority of the light sources may be configured to emit light predominantly in the infrared spectrum of wavelengths between 800 nm to 1300 nm.

In some implementations of the apparatus, each of the one or more light sources may be configured to emit light predominantly in the blue spectrum of wavelengths between 400 nm to 490 nm, light predominantly in the infrared spectrum of wavelengths between 800 nm to 1300 nm, or light predominantly in the blue and infrared spectrums of wavelengths between 400 nm to 490 nm and 800 nm to 1300 nm, respectively.

In some implementations of the apparatus, each of the one or more light sources may be configured to emit light predominantly in the blue spectrum of wavelengths between 400 nm to 490 nm.

In some implementations of the apparatus, each of the one or more light sources may be configured to emit light predominantly in the infrared spectrum of wavelengths between 800 nm to 1300 nm.

In some implementations of the apparatus, each of the one or more light sources may be configured to emit light predominantly in the blue spectrum of wavelengths between 400 nm to 490 nm, light predominantly in the infrared spectrum of wavelengths between 800 nm to 1300 nm, or light predominantly in the blue and infrared spectrums of wavelengths between 400 nm to 490 nm and 800 nm to 1300 nm, respectively.

In some implementations of the apparatus, at least one of the one or more light sources may be an incandescent infrared lamp, an infrared light emitting diode, or a blue light emitting diode.

In some implementations of the apparatus, the one or more light sources may include a plurality of light emitting diodes (LEDs) distributed throughout a circular or annular area.

In some implementations of the apparatus, the apparatus may further include one or more windows, each window being interposed between one of the one or more light sources and the wafer support surface. In at least such implementations, the one or more windows may each have a region that may be optically transmissive to light at least having a wavelength or wavelengths in a range or ranges between 400 nm to 490 nm, between 800 nm to 1300 nm, or between 400 nm to 490 nm and between 800 nm to 1300 nm.

In some implementations of the apparatus, the one or more windows may include aluminum oxide or silicon oxide.

In some implementations of the apparatus, the gas distribution system may include a showerhead that extends over, and may be vertically offset from, the wafer support surface, and at least some of the outlets may be distributed across, and extend through, a first portion of a faceplate of the showerhead having a first surface that faces towards the wafer support surface.

In some implementations of the apparatus, the one or more light sources may include a plurality of light-emitting diodes (LEDs), and the LEDs in the plurality of LEDs may be distributed across a second portion of the faceplate.

In some implementations of the apparatus, the LEDs in the plurality of LEDs may be interspersed between the outlets located within the second portion of the faceplate.

In some implementations of the apparatus, the first portion and the second portion may both be circular, annular, or radially symmetric in shape and may be centered on one another.

In some implementations of the apparatus, the showerhead may be interposed between the wafer support surface and at least some of the one or more light sources, and the showerhead may have a region that may be at least partially optically transmissive to light having a wavelength or wavelengths in a range or ranges between 400 nm to 490 nm, between 800 nm to 1300 nm, or between 400 nm to 490 nm and between 800 nm to 1300 nm.

In some implementations of the apparatus, the showerhead may include a faceplate having the outlets distributed thereacross, and at least the faceplate of the showerhead may be made of a material including silicon oxide or aluminum oxide.

In some implementations of the apparatus, the apparatus may further include one or more windows (or already have on or more such windows), each window interposed between one of the one or more light sources and the wafer support surface. In such implementations, the one or more windows may seal a corresponding one or more apertures of the processing chamber, and the one or more light sources may be located outside of the processing chamber and may be positioned to emit light through the one or more windows and into the processing chamber.

In some implementations of the apparatus, the apparatus may further include one or more windows (or already have on or more such windows), each window interposed between one of the one or more light sources and the wafer support surface. In such implementations, the one or more light sources may be light emitting diodes located within the processing chamber and at least some of the one or more windows may be located within the processing chamber as well.

In some implementations of the apparatus, the apparatus may further include a controller configured to: a) determine that a wafer within the processing chamber is to be prepared for a dry development process, b) cause the pedestal cooling system to cool the wafer to a temperature in a first temperature range while the wafer is supported by the wafer support surface, c) cause the gas distribution system to flow a first set of one or more processing gases through the plurality of outlets and across the wafer while the temperature of the wafer is in the first temperature range to perform the dry development process, and d) cause the one or more light sources to illuminate the wafer after (c) to heat the wafer to a temperature in a second temperature range with a lower limit higher than an upper limit of the first temperature range.

In some implementations of the apparatus, the apparatus may further include a pyrometer configured to obtain temperature measurements of the wafer at least during (d) and the controller may be further configured to: monitor the temperature of the wafer using the pyrometer, and adjust an intensity level of the one or more light sources based on the temperature of the wafer so as to keep the temperature of the wafer below 200° C.

In some implementations of the apparatus, the controller may be further configured to: (e) cause an inert gas to flow through the gas distribution system and the outlets thereof after (c) and to perform (d) after or during (e).

In some implementations of the apparatus, the inert gas may include argon, nitrogen, xenon, helium, krypton, or combinations of any two or more thereof.

In some implementations of the apparatus, the apparatus may further include an exhaust system connected with the processing chamber, and the controller may be further configured to: cause the exhaust system to evacuate gas from the processing chamber during at least part of (e), and perform (d) after a residual molar density of the first set of one or more process gases within the processing chamber is reduced to 10% or less of the molar density of the first set of one or more processes gases within the processing chamber during steady-state gas flow occurring during (c).

In some implementations of the apparatus, the controller may be configured to cause the one or more light sources to illuminate the wafer prior to (b) to heat the wafer to a temperature within a third temperature range.

In some implementations of the apparatus, the apparatus may further include a lift pin mechanism having a plurality of lift pins. In such implementations, the lift pin mechanism may be configured such that the lift pins may be controllably movable between a first position and a second position relative to the pedestal, each lift pin, in the first position, may not extend upward past the wafer support surface, each lift pin, in the second position, may extend upward past the wafer support surface, and the controller may be configured to cause the lift pins of the lift pin mechanism to be in the first position during at least part of both (b) and (c).

In some implementations of the apparatus, the controller may be configured to cause the lift pins of the lift pin mechanism to be in the second position during at least part of (d).

In some implementations of the apparatus, the controller may be configured to cause the one or more light sources to illuminate the wafer prior to (b) to heat the wafer to a temperature within a third temperature range, and to cause the lift pins of the lift pin mechanism to be in the second position during at least part of the illumination of the wafer prior to (b).

In some implementations of the apparatus, the controller may be configured to receive a command to perform a chamber cleaning operation, cause a cleaning wafer to be placed within the first chamber, the cleaning wafer has a reflective, high-diffusivity finish on a surface thereof, cause the one or more light sources to illuminate the surface of the cleaning wafer with the reflective, high-diffusivity finish for a first period of time, and remove the cleaning wafer from the first chamber after the first period of time.

In some implementations of the apparatus, the reflective, high-diffusivity coating may be made of tin, tellurium, or hafnium.

In some implementations of the apparatus, the surface with the reflective, high-diffusivity finish may have a surface roughness with a magnitude equivalent to one to two wavelengths of the light from the one or more light sources that illuminates the wafer.

In some implementations of the apparatus, the apparatus may further include the cleaning wafer.

In some implementations, an apparatus may be provided that includes a first chamber, a second chamber, a passage configured to connect the first chamber and the second chamber, the passage sized to permit a wafer to be moved therethrough and along a first path between the first chamber and the second chamber, a pedestal located within the first chamber and having a wafer support surface configured to support a wafer during dry development processing of the wafer within the first chamber, a pedestal cooling system configured to cool at least the wafer support surface of the pedestal, a gas distribution system with one or more inlets and a plurality of outlets, the gas distribution system configured to direct gas flowed therethrough out of the outlets into a region above the wafer support surface of the pedestal, and one or more light sources positioned in at least one of: within the first chamber and adjacent to the passage, within the passage, or within the second chamber, the one or more light sources may be configured to direct light at a location through which a wafer will transit when being moved from the first chamber and through the second chamber.

In some implementations of the apparatus, the passage may include a valve mechanism configured to seal the passage when in a first configuration, and the one or more light sources may be proximate a side of the valve mechanism closest to the pedestal.

In some implementations of the apparatus, the passage may include a valve mechanism configured to seal the passage when in a first configuration, and the one or more light sources may be proximate a side of the valve mechanism furthest from the pedestal.

In some implementations of the apparatus, the passage may include a valve mechanism configured to seal the passage when in a first configuration, the one or more light sources may be a plurality of light sources, and the one or more light sources may include a first set of one or more of the light sources that may be positioned such that the valve mechanism may be interposed between the first set of light sources and the pedestal and a second set of one or more of the light sources that may be positioned so as to be horizontally interposed between the valve mechanism and the pedestal.

In some implementations of the apparatus, the one or more light sources may be configured to generate at least an elongate illumination area of at least width D in a direction perpendicular to the first path and in a first reference plane when powered (wherein D is a diameter of the wafer).

In some implementations of the apparatus, the second chamber may be a vacuum transfer module having one or more wafer handling robots.

In some implementations of the apparatus, the apparatus may further include a controller configured to: a) determine that a wafer within the first chamber is to be prepared for a dry development process, b) cause the pedestal cooling system to cool the wafer to a temperature in a first temperature range while the wafer is supported by the wafer support surface, c) cause the gas distribution system to flow a first set of one or more processing gases through the plurality of outlets and across the wafer while the temperature of the wafer is in the first temperature range to perform the dry development process, d) cause the wafer to be removed from the wafer support surface, out of the first chamber, through the passage, and through the second chamber, and e) cause the one or more light sources to illuminate the wafer after the wafer has been removed from the wafer support surface and while the wafer is being moved out of the first chamber in order to heat the wafer to a temperature in a second temperature range with a lower limit higher than an upper limit of the first temperature range.

In some implementations of the apparatus, the apparatus may further include an exhaust system configured to evacuate gas from the first chamber when powered, and the controller may be configured to cause the exhaust system to activate to maintain a lower pressure within the first chamber than within the second chamber during at least part of (d) and (e).

In some implementations of the apparatus, the controller may be configured to cause the one or more light sources to illuminate the wafer while the wafer is moved into the first chamber from the second chamber prior to (a) in order to heat the wafer to a temperature in a third temperature range with a lower limit higher than an upper limit of the first temperature range.

In some implementations of the apparatus, the apparatus may further include an exhaust system configured to evacuate gas from the first chamber when powered (if not already included). The controller may be configured to: f) cause the one or more light sources to illuminate the wafer while the wafer is moved into the first chamber from the second chamber prior to (a) in order to heat the wafer to a temperature in a third temperature range with a lower limit higher than an upper limit of the first temperature range, and g) cause the exhaust system to activate to maintain a lower pressure within the first chamber than within the second chamber during at least part of (f).

In some implementations of the apparatus, the second chamber may have an internal volume that may be larger than a cylindrical reference volume of diameter D (wherein D is a diameter of the wafer), and the one or more light sources may be arranged so as to illuminate a circular region of diameter D within the second chamber and in a first reference plane.

In some implementations of the apparatus, the apparatus may further include a transfer module including one or more wafer handling robots, and the second chamber may be interposed between the first chamber and the transfer module.

In some implementations of the apparatus, the apparatus may further include a controller configured to: a) determine that a wafer within the first chamber is to be prepared for a dry development process, b) cause the pedestal cooling system to cool the wafer to a temperature in a first temperature range while the wafer is supported by the wafer support surface, c) cause the gas distribution system to flow a first set of one or more processing gases through the plurality of outlets and across the wafer while the temperature of the wafer is in the first temperature range to perform the dry development process, d) cause the wafer to be removed from the wafer support surface, out of the first chamber, through the passage, and into the second chamber, and e) cause the one or more light sources to illuminate the wafer after the wafer has been moved from the first chamber to the second chamber in order to heat the wafer to a temperature in a second temperature range with a lower limit higher than an upper limit of the first temperature range.

In some implementations of the apparatus, the controller may be configured to cause the one or more light sources to illuminate the wafer while the wafer is resident in the second chamber prior to being moved into the first chamber and prior to (a) in order to heat the wafer to a temperature in a third temperature range with a lower limit higher than an upper limit of the first temperature range.

In some implementations of the apparatus, at least one of the one or more light sources may be configured to emit light predominantly in the blue spectrum of wavelengths between 400 nm to 490 nm, light predominantly in the infrared spectrum of wavelengths between 800 nm to 1300 nm, or light predominantly in the blue and infrared spectrums of wavelengths between 400 nm to 490 nm and 800 nm to 1300 nm, respectively.

In some implementations of the apparatus, at least one of the one or more light sources may be configured to emit light predominantly in the blue spectrum of wavelengths between 400 nm to 490 nm.

In some implementations of the apparatus, at least one of the one or more light sources may be configured to emit light predominantly in the infrared spectrum of wavelengths between 800 nm to 1300 nm.

In some implementations of the apparatus, there may be a plurality of light sources and at least a majority of the light sources may be configured to emit light predominantly in the blue spectrum of wavelengths between 400 nm to 490 nm, light predominantly in the infrared spectrum of wavelengths between 800 nm to 1300 nm, or light predominantly in the blue and infrared spectrums of wavelengths between 400 nm to 490 nm and 800 nm to 1300 nm, respectively.

In some implementations of the apparatus, there may be a plurality of light sources and at least a majority of the light sources may be configured to emit light predominantly in the blue spectrum of wavelengths between 400 nm to 490 nm.

In some implementations of the apparatus, there may be a plurality of light sources and at least a majority of the light sources may be configured to emit light predominantly in the infrared spectrum of wavelengths between 800 nm to 1300 nm.

In some implementations of the apparatus, each of the one or more light sources may be configured to emit light predominantly in the blue spectrum of wavelengths between 400 nm to 490 nm, light predominantly in the infrared spectrum of wavelengths between 800 nm to 1300 nm, or light predominantly in the blue and infrared spectrums of wavelengths between 400 nm to 490 nm and 800 nm to 1300 nm, respectively.

In some implementations of the apparatus, each of the one or more light sources may be configured to emit light predominantly in the blue spectrum of wavelengths between 400 nm to 490 nm.

In some implementations of the apparatus, each of the one or more light sources may be configured to emit light predominantly in the infrared spectrum of wavelengths between 800 nm to 1300 nm.

In some implementations of the apparatus, each of the one or more light sources may be configured to emit light predominantly in the blue spectrum of wavelengths between 400 nm to 490 nm, light predominantly in the infrared spectrum of wavelengths between 800 nm to 1300 nm, or light predominantly in the blue and infrared spectrums of wavelengths between 400 nm to 490 nm and 800 nm to 1300 nm, respectively.

In some implementations of the apparatus, each light source of the one or more light sources may be an incandescent infrared lamp, an infrared light emitting diode, or a blue light emitting diode.

In some implementations, a method may be provided that includes a) placing a wafer on a wafer support surface of a pedestal in a processing chamber, b) cooling the wafer to a temperature in a first temperature range while the wafer is supported by the wafer support surface, c) flowing a first set of one or more processing gases through a plurality of outlets of a gas distribution system and across the wafer while the temperature of the wafer is in the first temperature range to perform a dry development process, and d) illuminating the wafer with one or more light sources after (c) and within the processing chamber to heat the wafer to a temperature in a second temperature range with a lower limit higher than an upper limit of the first temperature range.

In some implementations of the method, at least one of the one or more light sources may be configured to emit light predominantly in the blue spectrum of wavelengths between 400 nm to 490 nm, light predominantly in the infrared spectrum of wavelengths between 800 nm to 1300 nm, or light predominantly in the blue and infrared spectrums of wavelengths between 400 nm to 490 nm and 800 nm to 1300 nm, respectively.

In some implementations of the method, at least one of the one or more light sources may be configured to emit light predominantly in the blue spectrum of wavelengths between 400 nm to 490 nm.

In some implementations of the method, at least one of the one or more light sources may be configured to emit light predominantly in the infrared spectrum of wavelengths between 800 nm to 1300 nm.

In some implementations of the method, there may be a plurality of light sources and at least a majority of the light sources may be configured to emit light predominantly in the blue spectrum of wavelengths between 400 nm to 490 nm, light predominantly in the infrared spectrum of wavelengths between 800 nm to 1300 nm, or light predominantly in the blue and infrared spectrums of wavelengths between 400 nm to 490 nm and 800 nm to 1300 nm, respectively.

In some implementations of the method, there may be a plurality of light sources and at least a majority of the light sources may be configured to emit light predominantly in the blue spectrum of wavelengths between 400 nm to 490 nm.

In some implementations of the method, there may be a plurality of light sources and at least a majority of the light sources may be configured to emit light predominantly in the infrared spectrum of wavelengths between 800 nm to 1300 nm.

In some implementations of the method, each of the one or more light sources may be configured to emit light predominantly in the blue spectrum of wavelengths between 400 nm to 490 nm, light predominantly in the infrared spectrum of wavelengths between 800 nm to 1300 nm, or light predominantly in the blue and infrared spectrums of wavelengths between 400 nm to 490 nm and 800 nm to 1300 nm, respectively.

In some implementations of the method, each of the one or more light sources may be configured to emit light predominantly in the blue spectrum of wavelengths between 400 nm to 490 nm.

In some implementations of the method, each of the one or more light sources may be configured to emit light predominantly in the infrared spectrum of wavelengths between 800 nm to 1300 nm.

In some implementations of the method, each of the one or more light sources may be configured to emit light predominantly in the blue spectrum of wavelengths between 400 nm to 490 nm, light predominantly in the infrared spectrum of wavelengths between 800 nm to 1300 nm, or light predominantly in the blue and infrared spectrums of wavelengths between 400 nm to 490 nm and 800 nm to 1300 nm, respectively.

In some implementations of the method, each light source of the one or more light sources may be an incandescent infrared lamp, an infrared light emitting diode, or a blue light emitting diode.

In some implementations of the method, the one or more light sources may include a plurality of light emitting diodes (LEDs) distributed throughout a circular or annular area.

In some implementations of the method, the method may further include directing the light from the one or more light sources through one or more windows, each window interposed between one of the one or more light sources and the wafer support surface, the one or more windows each have a region that may be optically transmissive to light at least having a wavelength or wavelengths in a range of between 400 nm to 490 nm, between 800 nm to 1300 nm, or between 400 nm to 490 nm and 800 nm to 1300 nm.

In some implementations of the method, the one or more windows may be made from a material comprising aluminum oxide or silicon oxide.

In some implementations of the method, the gas distribution system may include a showerhead that extends over, and may be vertically offset from, the wafer support surface, and at least some of the outlets may be distributed across, and extend through, a first portion of a faceplate of the showerhead having a first surface that faces towards the wafer support surface.

In some implementations of the method, the one or more light sources may include a plurality of light-emitting diodes (LEDs), and the LEDs in the plurality of LEDs may be distributed across a second portion of the faceplate.

In some implementations of the method, the LEDs in the plurality of LEDs may be interspersed between the outlets located within the second portion of the faceplate.

In some implementations of the method, the first portion and the second portion may both be circular, annular, or radially symmetric in shape and may be centered on one another.

In some implementations of the method, the showerhead may be interposed between the wafer support surface and at least some of the one or more light sources, and the showerhead may have a region that may be at least partially optically transmissive to light having a wavelength or wavelengths in a range or ranges between 400 nm to 490 nm, between 800 nm to 1300 nm, or between 400 nm to 490 nm and between 800 nm to 1300 nm.

In some implementations of the method, the showerhead may include a faceplate having the outlets distributed thereacross, and at least the faceplate of the showerhead may be made of a material comprising silicon oxide or aluminum oxide.

In some implementations of the method, the method may further include, if it does not already include, emitting the light from the one or more light sources through one or more windows, each window interposed between one of the one or more light sources and the wafer support surface. In such implementations, the one or more windows may seal a corresponding one or more apertures of the processing chamber, and the one or more light sources may be located outside of the processing chamber and may be positioned to emit light through the one or more windows and into the processing chamber.

In some implementations of the method, the method may further include, if it does not already include, emitting the light from the one or more light sources through one or more windows, each window interposed between one of the one or more light sources and the wafer support surface. In such methods, the one or more light sources may be light emitting diodes located within the processing chamber and at least some of the one or more windows may be located within the processing chamber as well.

In some implementations of the method, the method may further include monitoring the temperature of the wafer using a pyrometer, and adjusting an intensity level of the one or more light sources based on the temperature of the wafer so as to keep the temperature of the wafer below 200° C.

In some implementations of the method, the method may further include (e) causing an inert gas to flow through the gas distribution system and the outlets thereof after (c), and performing (d) after or during (e).

In some implementations of the method, the inert gas may include argon, nitrogen, xenon, helium, krypton, or combinations of any two or more thereof.

In some implementations of the method, the method may further include causing an exhaust system to evacuate gas from the processing chamber during at least part of (e), and performing (d) after a residual molar density of the first set of one or more process gases within the processing chamber is reduced to 10% or less of the molar density of the first set of one or more processes gases within the processing chamber during steady-state gas flow occurring during (c).

In some implementations of the method, the method may further include illuminating the wafer prior to (b) to heat the wafer to a temperature within a third temperature range.

In some implementations of the method, the method may further include causing lift pins of a lift pin mechanism to be in a first position during at least part of both (b) and (c), the lift pins being controllably movable between the first position and a second position relative to the pedestal. In such implementations, each lift pin, in the first position, may not extend upward past the wafer support surface, and each lift pin, in the second position, may extend upward past the wafer support surface.

In some implementations of the method, the method may further include causing the lift pins of the lift pin mechanism to be in the second position during at least part of (d).

In some implementations of the method, the method may further include causing the one or more light sources to illuminate the wafer prior to (b) to heat the wafer to a temperature within a third temperature range, and causing the lift pins of the lift pin mechanism to be in the second position during at least part of the illumination of the wafer prior to (b).

In some implementations of the method, the method may further include receiving a command to perform a chamber cleaning operation, causing a cleaning wafer to be placed within the first chamber, the cleaning wafer has a reflective, high-diffusivity coating, causing the one or more light sources to illuminate the cleaning wafer for a first period of time, and removing the cleaning wafer from the first chamber after the first period of time.

In some implementations of the method, the reflective, high-diffusivity coating may be made of tin, hafnium, or tellurium.

In some implementations of the method, the surface with the reflective, high-diffusivity finish may have a surface roughness with a magnitude equivalent to one to two wavelengths of the light from the one or more light sources used to illuminate the wafer.

In some implementations, a method may be provided that includes a) placing a wafer on a wafer support surface of a pedestal in a processing chamber, b) cooling the wafer to a temperature in a first temperature range while the wafer is supported by the wafer support surface, c) flowing a first set of one or more processing gases through a plurality of outlets of a gas distribution system and across the wafer while the temperature of the wafer is in the first temperature range to perform a dry development process, d) moving the wafer from the first chamber via a passage to a second chamber connected to the first chamber by the passage, and e) illuminating the wafer with one or more light sources after (c) and while the wafer is either transiting the passage or within the second chamber in order to heat the wafer to a temperature in a second temperature range with a lower limit higher than an upper limit of the first temperature range.

In some implementations of the method, the passage may include a valve mechanism configured to seal the passage when in a first configuration, and the one or more light sources may be proximate a side of the valve mechanism closest to the pedestal.

In some implementations of the method, the passage may include a valve mechanism configured to seal the passage when in a first configuration, and the one or more light sources may be proximate a side of the valve mechanism furthest from the pedestal.

In some implementations of the apparatus, the passage may include a valve mechanism configured to seal the passage when in a first configuration, the one or more light sources may be a plurality of light sources, and the one or more light sources may include a first set of one or more of the light sources that may be positioned such that the valve mechanism may be interposed between the first set of light sources and the pedestal and a second set of one or more of the light sources that may be positioned so as to be horizontally interposed between the valve mechanism and the pedestal.

In some implementations of the method, the one or more light sources may be configured to generate an elongate illumination area of at least width D in a direction perpendicular to the first path and in a first reference plane when powered (in which D is a diameter of the wafer).

In some implementations of the method, the second chamber may be a transfer module having one or more wafer handling robots.

In some implementations of the method, the method may further include causing an exhaust system to activate to maintain a lower pressure within the first chamber than within the second chamber during at least part of (d) and (e).

In some implementations of the method, the method may further include causing the one or more light sources to illuminate the wafer while the wafer is moved into the first chamber from the second chamber prior to (a) in order to heat the wafer to a temperature in a third temperature range with a lower limit higher than an upper limit of the first temperature range.

In some implementations of the method, the method may further include f) causing the one or more light sources to illuminate the wafer while the wafer is moved into the first chamber from the second chamber prior to (a) in order to heat the wafer to a temperature in a third temperature range with a lower limit higher than an upper limit of the first temperature range, and g) causing an exhaust system or the exhaust system to activate to maintain a lower pressure within the first chamber than within the second chamber during at least part of (f).

In some implementations of the method, the second chamber may have an internal volume that may be larger than a cylindrical reference volume of diameter D (in which D is a diameter of the wafer), and the one or more light sources may be arranged so as to illuminate a circular region of diameter D within the second chamber and in a first reference plane.

In some implementations of the method, there may be a transfer module including one or more wafer handling robots and the second chamber may be interposed between the first chamber and the transfer module.

In some implementations of the method, the method may further include causing the one or more light sources to illuminate the wafer while the wafer is resident in the second chamber prior to being moved into the first chamber and prior to (a) in order to heat the wafer to a temperature in a third temperature range with a lower limit higher than an upper limit of the first temperature range.

In some implementations of the method, at least one of the one or more light sources may be configured to emit light predominantly in the blue spectrum of wavelengths between 400 nm to 490 nm, light predominantly in the infrared spectrum of wavelengths between 800 nm to 1300 nm, or light predominantly in the blue and infrared spectrums of wavelengths between 400 nm to 490 nm and 800 nm to 1300 nm, respectively.

In some implementations of the method, at least one of the one or more light sources may be configured to emit light predominantly in the blue spectrum of wavelengths between 400 nm to 490 nm.

In some implementations of the method, at least one of the one or more light sources may be configured to emit light predominantly in the infrared spectrum of wavelengths between 800 nm to 1300 nm.

In some implementations of the method, there may be a plurality of light sources and at least a majority of the light sources may be configured to emit light predominantly in the blue spectrum of wavelengths between 400 nm to 490 nm, light predominantly in the infrared spectrum of wavelengths between 800 nm to 1300 nm, or light predominantly in the blue and infrared spectrums of wavelengths between 400 nm to 490 nm and 800 nm to 1300 nm, respectively.

In some implementations of the method, there may be a plurality of light sources and at least a majority of the light sources may be configured to emit light predominantly in the blue spectrum of wavelengths between 400 nm to 490 nm.

In some implementations of the method, there may be a plurality of light sources and at least a majority of the light sources may be configured to emit light predominantly in the infrared spectrum of wavelengths between 800 nm to 1300 nm.

In some implementations of the method, each of the one or more light sources may be configured to emit light predominantly in the blue spectrum of wavelengths between 400 nm to 490 nm, light predominantly in the infrared spectrum of wavelengths between 800 nm to 1300 nm, or light predominantly in the blue and infrared spectrums of wavelengths between 400 nm to 490 nm and 800 nm to 1300 nm, respectively.

In some implementations of the method, each of the one or more light sources may be configured to emit light predominantly in the blue spectrum of wavelengths between 400 nm to 490 nm.

In some implementations of the method, each of the one or more light sources may be configured to emit light predominantly in the infrared spectrum of wavelengths between 800 nm to 1300 nm.

In some implementations of the method, each of the one or more light sources may be configured to emit light predominantly in the blue spectrum of wavelengths between 400 nm to 490 nm, light predominantly in the infrared spectrum of wavelengths between 800 nm to 1300 nm, or light predominantly in the blue and infrared spectrums of wavelengths between 400 nm to 490 nm and 800 nm to 1300 nm, respectively.

In some implementations of the method, each light source of the one or more light sources may be an incandescent infrared lamp, an infrared light emitting diode, or a blue light emitting diode.

In addition to the above-listed implementations, other implementations evident from the discussion below and the Figures are to be understood to also fall within the scope of this disclosure.

### BRIEF DESCRIPTION OF THE FIGURES

Reference to the following Figures is made in the discussion below; the Figures are not intended to be limiting in scope and are simply provided to facilitate the discussion below.

FIG. 1 depicts an example apparatus that includes a processing chamber that may be used to perform a dry development process on a semiconductor wafer having a metal-containing photoresist deposited thereupon.

FIG. 2 depicts an apparatus having components similar to that of apparatus 100.

FIG. 3 depicts the apparatus of FIG. 1 but in a different use configuration.

FIG. 4 depicts an example apparatus that is similar in construction to the apparatus of FIG. 1 except that the one or more light sources are positioned within the processing chamber instead of outside of the processing chamber.

FIG. 5 depicts an example apparatus that is similar to that of FIG. 4 except that the one or more light sources have been replaced with a plurality of light sources that are distributed across the underside of the faceplate of a showerhead.

FIG. 6 depicts a detail view of an outer peripheral region of the showerhead of FIG. 5.

FIG. 7 depicts another apparatus that is similar to the apparatus of FIG. 5 except that the one or more light sources are arranged within the processing chamber so as to form several circular arrays centered on the showerhead.

FIG. 8 depicts a detail view of a portion of the light sources within the dashed-line rectangle shown in FIG. 7.

FIG. 9 depicts an example apparatus which includes a processing chamber that has one or more light sources positioned in a passage that connects the processing chamber with a second, adjacent chamber.

FIG. 10 depicts an example apparatus which includes a processing chamber that is connected via a passage with an adjacent chamber having one or more light sources that may be used to provide radiative heating to a wafer contained therewithin.

FIG. 11 depicts a flow chart of a technique for performing a dry development process followed by a post-dry-development bake operation.

FIG. 12 depicts a flow diagram of another technique for performing a dry development process followed by a post-dry-development bake operation.

FIG. 13 depicts a flow diagram of another technique for performing a dry development process followed by a post-dry-development bake operation.

FIG. 14 depicts a flow diagram of another technique for performing a dry development process followed by a post-dry-development bake operation.

FIG. 15 depicts a flow diagram of another technique for performing a dry development process followed by a post-dry-development bake operation.

FIG. 16 depicts a flow chart of an example cleaning process.

The above-described Figures are provided to facilitate understanding of the concepts discussed in this disclosure, and are intended to be illustrative of some implementations that fall within the scope of this disclosure, but are not intended to be limiting-implementations consistent with this disclosure and which are not depicted in the Figures are still considered to be within the scope of this disclosure.

### DETAILED DESCRIPTION

This disclosure relates generally to the field of semiconductor processing. In particular aspects, the disclosure is directed to processes and apparatuses for development of photoresists (e.g., EUV-sensitive metal and/or metal oxide-containing photoresists) using halide chemistries, for example to form a patterning mask in the context of EUV patterning. Such photoresists may, for example, be provided using either dry or wet deposition or coating techniques. Thus, a dry development technique may be used for appropriate photoresists that are dry deposited or, for example, applied through a wet process such as spin coating.

Reference is made herein in detail to specific embodiments of the disclosure. Examples of the specific embodiments are illustrated in the accompanying drawings. While the disclosure will be described in conjunction with these specific embodiments, it will be understood that it is not intended to limit the disclosure to such specific embodiments. On the contrary, it is intended to cover alternatives, modifications, and equivalents as may be included within the spirit and scope of the disclosure. In the following description, numerous specific details are set forth in order to provide a thorough understanding of the present disclosure. The present disclosure may be practiced without some or all of these specific details. In other instances, well known process operations have not been described in detail so as to not unnecessarily obscure the present disclosure.

### INTRODUCTION

Patterning of thin films in semiconductor processing is often an important step in the fabrication of semiconductors. Patterning involves lithography. In 193 nm photolithography, patterns are printed by emitting photons from a photon source through a mask, thereby exposing a region in the shape and form of the pattern on a photosensitive photoresist. This causes a chemical reaction in the photoresist that, after development, allows certain portions of the photoresist to be removed to form the pattern.

Advanced technology nodes (as defined by the International Technology Roadmap for Semiconductors) include nodes 22 nm, 16 nm, and beyond. In the 16 nm node, for example, the width of a typical via or line in a Damascene structure is typically no greater than about 30 nm. Scaling of features on advanced semiconductor integrated circuits (ICs) and other devices is driving lithography to improve resolution.

Extreme ultraviolet (EUV) lithography can extend lithography technology by moving to smaller imaging source wavelengths than would be achievable with non-EUV photolithography methods. EUV light sources at approximately 10-20 nm, or 11-14 nm wavelength, for example 13.5 nm wavelength, can be used for leading-edge lithography tools, also referred to as scanners. The EUV radiation is strongly absorbed in a wide range of solid and fluid materials including quartz and water vapor, and so operates in a vacuum.

EUV lithography makes use of EUV resists that are patterned to form masks for use in etching underlying layers. EUV resists may be polymer-based chemically amplified resists (CARs) produced by liquid-based spin-on techniques. An alternative to CARs is directly photopatternable metal oxide-containing films, such as those available from Inpria, Corvallis, OR, and described, for example, in US Patent Publications US 2017/0102612, US 2016/021660 and US 2016/0116839, incorporated by reference herein at least for their disclosure of photopatternable metal oxide-containing films. Such films may be produced by spin-on techniques or dry vapor-deposited. The metal oxide-containing film can be patterned directly (i.e., without the use of a separate photoresist) by EUV exposure in a vacuum ambient providing sub-30 nm patterning resolution, for example as described in U.S. Pat. No. 9,996,004, issued Jun. 12, 2018 and titled EUV PHOTOPATTERNING OF VAPOR-DEPOSITED METAL OXIDE-CONTAINING HARDMASKS, and/or in Application PCT/US19/31618, filed May 9, 2019, and titled METHODS FOR MAKING EUV PATTERNABLE HARD MASKS, the disclosures of which at least relating to the composition, deposition, and patterning of directly photopatternable metal oxide films to form EUV resist masks is incorporated by reference herein. Generally, the patterning involves exposure of the EUV resist with EUV radiation to form a photo pattern in the resist, followed by development to remove a portion of the resist according to the photo pattern to form the mask.

It should also be understood that the while present disclosure relates to lithographic patterning techniques and materials exemplified by EUV lithography, it is also applicable to other next generation lithographic techniques. In addition to EUV, which includes the standard 13.5 nm EUV wavelength currently in use and development, the radiation sources most relevant to such lithography are DUV (deep-UV), which generally refers to use of 248 nm or 193 nm excimer laser sources, X-ray, which formally includes EUV at the lower energy range of the X-ray range, as well as e-beam, which can cover a wide energy range. The specific methods may depend on the particular materials and applications used in the semiconductor substrate and ultimate semiconducting device. Thus, the methods described in this application are merely exemplary of the methods and materials that may be used in present technology.

Directly photopatternable EUV resists may be composed of or contain metals and/or metal oxides mixed within organic components. The metals/metal oxides are highly promising in that they can enhance the EUV photon adsorption and generate secondary electrons and/or show increased etch selectivity to an underlying film stack and device layers. To date, these resists have been developed using a wet (solvent) approach, which requires the wafer to be immersed in a developer solvent and then dried and baked. Wet development does not only limit productivity but can also lead to line collapse due to surface tension effects and/or delamination.

Dry development techniques have been proposed to overcome these issues by eliminating substrate delamination and interface failures. Dry development can improve performance (e.g., prevent line collapse due to surface tension and delamination effects encountered in wet development) and enhance throughput (e.g., by avoiding having to move the wafer through a wet development track). Other advantages may include eliminating the use of organic solvent developers, reduced sensitivity to adhesion issues, increased EUV absorption for improved dose efficiency, and a lack of solubility-based limitations. Dry development can also provide more tunability and give further critical dimension (CD) control and better scum free defect window.

Dry development has its own challenges, including management of byproducts that result from dry development processes. This disclosure is directed at enhancements to dry development processes and processing equipment.

### Development of EUV Resist

According to various aspects of the present disclosure, a photopatterned metal-containing photoresist is developed by exposure to halide-containing chemistries. An EUV-sensitive metal or metal oxide-containing film, e.g., an organotin oxide, is disposed on a semiconductor substrate. Various potential metal-containing photoresists may, for example, include photoresists that include tin, tellurium, hafnium with an organic ligand attached thereto that is an alkyl group with from 1 to 12 carbon atoms in it. The EUV-sensitive metal or metal oxide-containing film is patterned directly by EUV exposure in vacuum ambient. A pattern is then developed to form a resist mask using a development chemistry. In some embodiments, the development chemistry is a dry development chemistry. In some embodiments, the dry development chemistry may include hydrogen chloride (HCl), hydrogen bromide (HBr), or organohalides (or mixtures of two or more thereof), usually mixed with an inert carrier gas such as argon (Ar), helium (He), krypton (Kr), xenon (Xe), or nitrogen (N2) (or mixtures of two or more thereof) and, in some instances, less than 5% of oxygen and/or hydrogen. Such a dry development chemistry, e.g., containing halogen-donating gases such as those, for example, listed above, may be flowed across or over a wafer with a latent image (a photopatterned metal-containing photoresist) with the wafer being held to a temperature in the −40° to 40° C. range after the wafer has been exposed to an EUV patterning operation. Such dry development techniques may be done in chamber pressure environments in approximately the 5 mTorr to 600 mTorr range while using either a gentle plasma or a thermal process while flowing a dry development chemistry, e.g., a hydrogen and halide dry development chemistry.

Once the metal-containing photoresist has been exposed to the desired lithographic pattern, e.g., in an EUV scanner or similar patterning equipment, the exposed wafer may be moved to a dry development chamber for performance of a dry development process in order to remove either the exposed areas thereof (referred to as the latent image produced by the scanner) or the unexposed areas thereof. In some implementations, the exposed wafer may be subjected to a post-exposure bake (PEB)—a thermal process that may cause cleaved metal bonds, e.g., tin bonds in a tin-based alkoxy resist, to convert to metal-oxygen, e.g., tin-oxygen, bonds to form a material that is stoichiometrically close to a metal-oxide, e.g., tin-oxide, in the exposed areas. The unexposed areas during such a PEB may retain an alkyl ligand in one of the exposed valences of the metal, e.g., in one of the four valences of tin. The PEB may be performed after the wafer has been exposed but prior to performance of the dry development process. Typical PEBs may include, for example, PEBs in which the wafer is heated to a temperature or temperatures between 130° C. to 250° C. for a period of time between 30 seconds to 240 seconds. In some instances, a PEB process may include the performance of multiple PEBs, e.g., an initial PEB such as that discussed above, followed by a second PEB in which the wafer may be heated to a temperature or temperatures between 200° C. to 300° C. in a controlled ambient environment for a period of time between 30 seconds and 240 seconds.

During the dry development process, a set of one or more dry development gases may be flowed across the exposed surface of the wafer. The dry development gases may be selected so as to selectively attack/etch either the exposed areas or the unexposed areas of the wafer. For example, a halide-containing chemistry, e.g., hydrogen bromide, may be used to selectively remove the unexposed areas of a photoresist, e.g., an organotin resist, as described above. Such a halide-containing chemistry may attack alkyl groups that are still connected to the metal, e.g., alkyl groups that are still connected to tin, in the unexposed areas. In contrast, the alkyl groups that may have existed in the exposed areas may have previously been driven out of those exposed regions during the exposure process and the halide-containing chemistry may therefore generally not attack (or minimally attack) the exposed regions. For example, in a tin-based alkoxy resist, the development chemistry may cause the tin alkyl that may remain in the unexposed areas to be etched away, while the tin oxide that may remain, e.g., via the PEB, may remain generally intact.

During the dry development processes, heavier group 14 elements, e.g., silicon, germanium, and tin, may form volatile halides. However, the volatility of such halides decreases with increasing atomic weight of the group 14 elements, resulting in such halides remaining resident within etched features of the wafer. For example, if the development chemistry used is hydrogen-bromide and the photoresist is a tin-based alkoxy resist, tin-alkyl-bromide molecules may remain trapped within the etched features after the dry development process has completed. Such halides, if allowed to remain present, may outgas during subsequent stages of wafer handling and processing, potentially contaminating equipment, such as FOUPs (front-opening unified pods) used to transport wafers between semiconductor processing tools. Contamination of FOUPs, for example, may cause other wafers housed within the FOUPs to become contaminated, thereby further spreading the contamination.

The issue of volatile halides remaining resident on wafers after dry development processing may be exacerbated due to the relatively unique thermal environment used to perform some dry development processes. For example, the processing chamber in which dry development processing is performed may be designed to maintain the wafer at a temperature near zero Celsius, e.g., −10° C., during the dry development process, while the chamber itself (and most equipment within the chamber) are kept at a much higher temperature, e.g., 100° C. Such a low temperature may cause thermomotive forces to keep the low-volatility halides resident on the wafer or to encourage low-volatility halides to adsorb onto the wafer, e.g., the thermal gradient between the elevated-temperature walls and the lower-temperature wafer may cause volatile materials, such as low-volatility halides, that may be present within the processing chamber to migrate towards the wafer and then adsorb onto it.

The present inventors determined that it would be desirable to perform a post-dry-development bake (PDDB) on the wafer after the dry development process is performed in order to drive out such volatile halides that may remain on the wafer. Such a PDDB, for example, may be performed by heating the wafer to an elevated temperature, e.g., −180° C., which may be sufficient to drive out most or all of the resident volatile halides from the wafer.

Due to the large temperature differential between the desired PDDB wafer temperature, e.g., a temperature differential of −180° C. or greater (although 160° C. or greater may work as well), and the temperature of the wafer during dry development processing, e.g., ˜−10° C., heating the wafer to perform the PDDB may be problematic for a variety of reasons. For example, if the PDDB is performed in the same chamber as the chamber in which the dry development process is performed, this may allow the volatile halides that may be driven off of the wafer in the PDDB process to be evacuated using the same systems that are used to evacuate similar volatile halides that may actually be released from the wafer during the dry development processing. However, heating the wafer within the dry development chamber using conductive heating mechanisms, e.g., heating the wafer conductively using embedded heaters located within the pedestal, may be difficult to perform efficiently due to the large temperature differentials involved. For example, if embedded heaters within the pedestal are used to heat the wafer support surface and, through conduction, the wafer supported thereby, a significant fraction of the heat that is provided by such heaters may, instead of being used to heat the wafer, be used to heat the pedestal, which may have a much larger thermal mass compared to that of the wafer. As a result, it may take a significant amount of time (and power) to bring the wafer to the temperature at which the PDDB is to be performed. Similarly, it may then take a significant amount of time to return the pedestal to a cold-temperature state in which it can maintain a wafer at the dry development process temperature, e.g., −10° C. The time period(s) in which the pedestal is either heating up the wafer or cooling down in preparation for performing a dry development process on a subsequent wafer may increase the total time in which the dry development processing chamber cannot be used to process another wafer, thereby reducing the wafer throughput of such a dry development tool.

One alternative is to perform the PDDB in a separate chamber from the process chamber, e.g., moving the wafer after the dry development process into a separate chamber in which a heated pedestal is provided, thereby allowing the pedestal in the dry development process chamber to be largely kept at steady state, e.g., at a temperature that allows the wafers placed thereupon to be brought to a temperature of ˜−10° C., while a pedestal in the separate chamber may be maintained at a much hotter temperature, e.g., 180° C. to 250° C., such that a wafer placed thereupon may be rapidly heated to the desired PDDB temperature. While such an arrangement may avoid tying up the dry development chamber while waiting for heating/cooling of the pedestal to occur and during the PDDB, such an arrangement may require the use of an extra chamber, thereby incurring additional cost, and may still incur a throughput penalty since extra time must be taken to move the wafer from the dry development chamber, through a transfer module, and into the separate chamber in which the PDDB is to be performed. In some instances, there may also be an increased risk of backside contamination of the wafer, e.g., by tin, as it transits from the dry development chamber to the PDDB chamber. However, such implementations may nonetheless be advantageous in that they allow the dry development processing chamber to be used entirely for dry development processing, thereby increasing their potential throughput.

Another alternative that may be used in place of the PDDB is to perform a post-dry-development plasma flash within the dry development chamber. In such a system, the dry development chamber may be configured to generate a plasma after the dry development process is completed, thereby generating plasma-sourced vacuum ultraviolet and infrared radiation and bombarding the wafer with ions. This technique, however, may result in the accidental deposition of metal-containing particles on the wafer in some cases, which may contaminate the wafer with particulates. The ion bombardment may also result in corner rounding of the photoresist occurring, which may degrade the resulting pattern formed on the wafer.

After considering various options for performing the PDDB or similar procedure, the present inventors identified a completely different mechanism for performing the PDDB that allows for a reduced throughput penalty and/or cost and/or increased performance compared with the various options discussed above. In particular, the present inventors determined that heating the wafer radiatively after the dry development process was complete would allow the wafer to be rapidly heated to the desired PDDB temperature, e.g., ˜250° C., while potentially allowing such heating to be performed without requiring that the pedestal temperature be modified to provide the heating.

The radiative heating discussed herein may be performed using light sources that emit a broad spectrum of wavelengths, e.g., white light or light that otherwise includes a large range of wavelengths. However, the light sources used may also be specifically selected so as to predominantly emit light of particular wavelengths (or narrow wavelength ranges) in order to provide particular advantages. For example, a typical 300 mm diameter silicon wafer weighs approximately 125 grams. Based on a specific heat of silicon of 0.7 Joules/gram/° C., increasing the temperature of such a wafer by, for example, ˜260° C. would require delivery of at least 22.75 kJ of heat energy (e.g., between about 20 kJ to 30 kJ, taking into account potential variances in the amount of temperature increase, heat loss from the wafer, potential heating inefficiencies, etc.) to be radiatively transferred to the wafer during the PDDB process. The light source(s) used may be selected so as to be able to provide such high-magnitude radiative energy transfer. For example, one or more light sources selected so as to have a useful power delivered (in aggregate, in the event that plural light sources are used) in the 0.5 to 5 kW range may be used, in some implementations, to provide such radiative heating performance.

It will be understood that references to using “one or more light sources” in the discussions below to perform radiative heating refer to the use of a light source or light sources such as any of those discussed below. It will also be understood that such light sources may be provided in a variety of formats. For example, in some instances, a single light source may be used that provides a large illumination field. In some such implementations, for example, a filament-based (incandescent) infrared light source may be provided, e.g., an infrared bulb, and coupled with a parabolic or other reflector that may be configured to focus the light emitted therefrom into a generally circular illumination area that is equivalent to the size of a wafer. In other implementations, solid-state illumination devices, e.g., infrared- and/or blue-emitting light emitting diodes (LEDs) or similar devices may be used. For example, a plurality of surface-mount LEDs may be mounted to one or more substrates, e.g., printed circuit board(s) or flexible printed circuit(s), that may serve to both support the LEDs and also route power to them via electrical traces that may be located within or on the substrate(s). In some implementations, such LEDs may be arranged such that they form a generally circular, annular, or radially symmetric pattern so as to provide, in aggregate, a circular illumination zone. In other implementations, multiple LEDs may be arranged in other patterns, e.g., elongate patterns such as linear arrays or rectangular arrays, so as to provide other illumination area shapes.

Given that LEDs are generally much more energy-efficient than incandescent light sources, the use of a large array of LEDs as the light source(s) may allow for the desired radiative heat transfer to occur with much lower waste heat loss via the light source(s) as compared with an equivalent incandescent light source. For example, LEDs may convert approximately 40% of the electrical power provided thereto into light (this may vary depending on the wavelength of light emitted by the LED), with the remaining electrical power being dissipated as waste heat from the LEDs, i.e., not generally usable for radiative heating. In comparison, an incandescent bulb may convert approximately 5% of the electrical power provided thereto into light, with the remaining electrical power being dissipated as waste heat. The use of LEDs may thus both significantly reduce the overall power consumption of the radiative heating system as compared with the use of incandescent light sources and also significantly reduce the amount of waste heat that needs to be disposed of in order to prevent overheating of the light source(s).

Various types of LEDs may be employed in such light sources. Examples include chip-on-board (COB) LEDs or surface-mounted diode (SMD) LEDs. For SMD LEDs, the LED chip may be fused to a printed circuit board (PCB) that may have multiple electrical contacts allowing for the control of each diode on the chip. For example, a single SMD chip is typically limited to having three diodes (e.g., red, blue, or green) that can be individually controllable to create different colors, for instance (or may have fewer diodes, e.g., a single diode providing a particular narrow wavelength range of light). SMD LED chips may range in size, such as 2.8×2.5 mm, 3.0×3.0 mm, 3.5×2.8 mm, 5.0×5.0 mm, and 5.6×3.0 mm. For COB LEDs, each chip can have more than three diodes, such as nine, 12, tens, hundreds or more, provided on the same substrate. COB LED chips typically have one circuit and two contacts regardless of the number of diodes present, thereby providing a simple design and efficient single-color application.

If LED-based light sources are used, it may be particularly advantageous to use LEDs that emit light predominantly in the violet, indigo, and/or blue spectrum, e.g., in the 400 nm to 490 nm wavelength range, and/or the high orange, red, near infrared, and/or infrared spectrum, e.g., in the 600 nm to 1300 nm wavelength range. It will be understood that, as used herein, a light source that emits light predominantly in a particular wavelength range is a light source that emits 80% or more of its photonic energy in that particular wavelength range. Thus, a light source that emits predominantly blue light would emit at least 80% of its light energy in wavelengths within the blue spectrum. It will be understood that such a light source may include an individual single-color LED or a multicolor LED that is controlled to only emit light in such a manner during at least some portion of radiative heating. For example, multi-color LEDs typically consist of multiple single-color (or narrow-spectrum) LEDs, each limited to emitting light in a different wavelength spectrum, e.g., a red LED, a green LED, and a blue LED. Such multi-color LEDs may be controlled such that the blue LED is on and the green and red LEDs are off (or operating at a much lower intensity than the blue LED) such that 80% or more of the light energy emitted by the multi-color LED is in the blue spectrum.

By limiting the wavelength range of the LEDs used, it may be possible to even further increase the power efficiency of the light source(s). For example, LEDs that emit light in predominantly the blue spectrum have historically had a power conversion efficiency (a ratio of radiant flux to input electrical power) that is higher than LEDs that emit light in the predominantly red, green, or amber spectra, or that emit light in a broad spectrum, e.g., white light. For example, LEDs that emit light in predominantly the blue spectrum may have a ratio of radiant flux to input electrical power that is ˜50% higher than that of LEDs that emit light in predominantly the red spectrum, ˜200% higher than that of LEDs that emit light in predominantly the green spectrum, and ˜500% higher than that of LEDs that emit light in predominantly the amber spectrum. Broad-spectrum LEDs, e.g., white light LEDs, may either be composed of multiple, different color LEDs (e.g., red, green, blue) that emit light simultaneously in order to produce mixed-wavelength white light (in which case the relative inefficiency of the red and green LEDs will offset the efficiency of the blue LED that is used, or may be a blue LED that is coupled with a phosphor that, when stimulated with blue-wavelength light, emits white light; the phosphor stimulation process, however, incurs its own efficiency penalty, thus effectively reducing the ratio of radiant flux to input electrical power of the blue LED used to stimulate the phosphor.

LEDs that emit light primarily in the blue spectrum may thus offer significant power savings and reduced waste heat compared with other visible-spectrum LEDs. Moreover, light that is in the blue spectrum is readily absorbed by a silicon wafer regardless of whether or not it is doped silicon or intrinsic silicon, resulting in little or no radiative heating of the structure beneath a silicon wafer, e.g., a wafer support or pedestal. For example, light in the blue spectrum may be completely absorbed in intrinsic silicon within a micrometer or so from the surface on which the blue light is incident. This results in all or nearly all of the radiant blue-spectrum (or near-blue spectrum) energy to which a silicon wafer is exposed being absorbed by the wafer and thus used to heat the wafer.

LEDs that emit light predominantly in the infrared and/or near-infrared spectrum, e.g., as discussed above, may offer similar benefits to LEDs that emit light predominantly in the blue spectrum with respect to LEDs that emit light predominantly in the green or amber spectra or that emit broad-spectrum light, e.g., white light. Infrared light from infrared LEDs (and other infrared light sources) may, however, not be entirely absorbed in some silicon wafers, however, due to the greater penetration distance that infrared wavelength light has in silicon as compared with blue wavelength light. As a result, there may be some increased possibility of structures located behind the wafer being radiatively heated by infrared light that passes through the wafer without being absorbed/used to radiatively heat the wafer. Doped silicon wafers, however, may have greater absorption characteristics, however, thereby mitigating the potential for bleed-through of infrared energy through the wafer to the structures underneath the wafer.

A light source or sources other than LED sources may alternatively be used, e.g., incandescent lamps. In particular, incandescent lamps may be used, although incandescent lamps may consume considerably more power for a given level of radiative heating than may be consumed by LEDs configured to provide the same level of radiative heating. While most incandescent lamps offer poor power conversion efficiency, as discussed above, infrared incandescent lamps actually have a high power conversion efficiency in comparison.

As noted above, the wafer may be illuminated with one or more light sources that emit light at least within a particular wavelength range or ranges. For example, as discussed above, the one or more light sources may be selected so as to emit light in the violet, indigo, and/or blue spectrum (400 nm to 490 nm wavelength range) and/or light in the upper orange, red, and/or infrared spectrum (600 nm to 1300 nm wavelength range). Other wavelengths or wavelength ranges may be used as well, although such ranges may not produce the various benefits discussed above. The spectrum(s) of light used may be selected so as to efficiently heat the wafer through radiative heating while keeping the photon energies that are involved to be generally less than the bond energy of various dry development byproduct molecules, e.g., tin-halo-alkyls and oxidizers, that may be present within the dry development chamber after the dry development process is completed. For example, the wavelength(s) of the light used for radiative heating may be selected so as to have a photon energy that is below about 2.5 eV. In some implementations, wavelengths of light used for radiative heating may be selected so as to have photon energies that are below about 3.0 eV. While this may be higher than the bond energy of some of the dry development byproduct molecules that may be present and thus present an increased chance of photocleavage of those molecules, the probability of photon matter interaction with the byproduct molecules may actually be low enough, especially at the low pressures that may be present within the processing chamber during the radiative heating, that inadvertent gas phase decomposition either does not occur or occurs at a rate that does not unacceptably adversely affect the wafer. For example, while dry deposition operations may be performed at chamber pressures of between 5 mTorr and 600 mTorr, post-dry development bake operations may be performed at low pressures, e.g., in the 0.1 mTorr to 100 mTorr range. PEB operations may be performed in a similar pressure environment but may also be performed in chamber pressure environments ranging up to atmospheric pressure, e.g., 760 Torr. Infrared light or near-infrared light in the 600 nm to 1300 nm range may have photon energies in the ˜2 eV to ˜0.95 eV range and will therefore be too low to cause photo ionization or bond cleavagep of gas molecules that may still be resident in the processing chamber. At the same time, infrared or near-infrared radiation in the 600 nm to 1130 nm range will generally be completely absorbed in intrinsic silicon within 1 mm of the surface of the silicon through which such radiation is introduced. For doped silicon, the presence of dopants may drastically decrease the absorption depth such that all or nearly all infrared or near-infrared radiation in the 600 nm to 1300 nm range will be completely absorbed by the silicon within the thickness range of a standard semiconductor wafer, e.g., ˜775 micrometers.

Such radiative heating may be performed in a variety of ways and in a variety of structures. Various examples of such structures are discussed below.

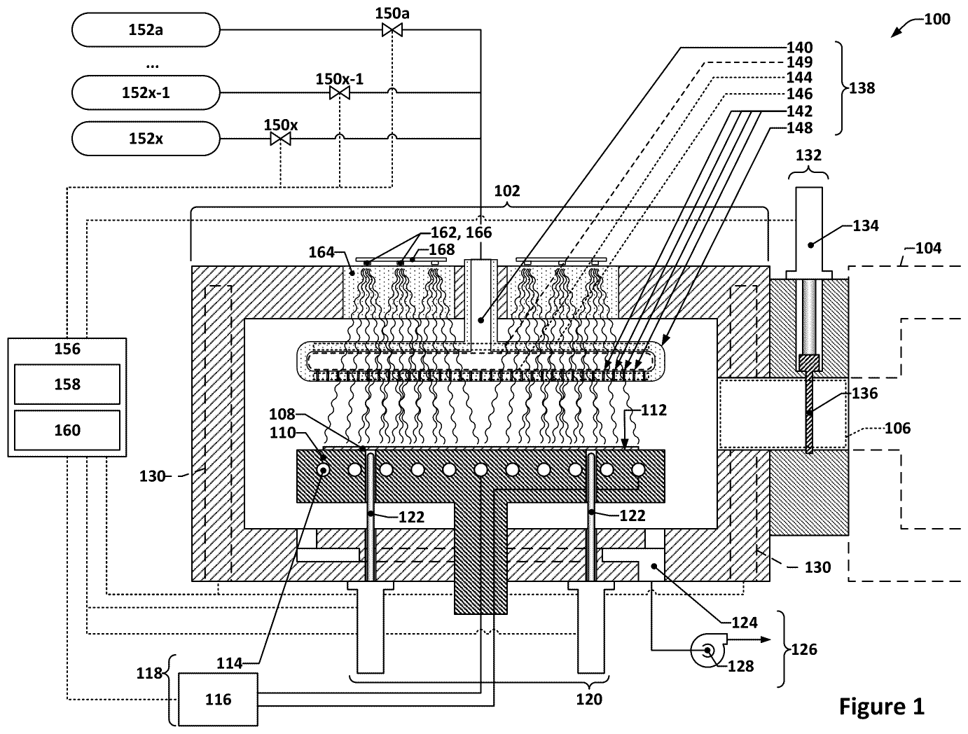

FIGS. 1 through 9 depict various example apparatuses that may share many components or features in common. In view of this commonality, elements that are referred to with a similar reference number in each Figure may be assumed to be similar in structure, function, and characteristics unless indicated otherwise.

FIG. 1 depicts an example apparatus 100 that includes a processing chamber 102 that may be used to perform a dry development process on a semiconductor wafer (also referred to simply as a wafer herein) 108 having a metal-containing photoresist deposited thereupon. The wafer 108 may have been previously exposed to EUV radiation in a lithographic patterning operation, e.g., in a scanner. The processing chamber 102 may include a pedestal 110 that may receive the wafer 108 and support it on a wafer support surface 112 thereof during subsequent dry development processes.

The pedestal 110 may incorporate elements of a pedestal cooling system 118 that may, for example, include one or more cooling passages 114 that are fluidically connected with a cooling unit 116. The cooling unit 116 may, for example, be an external chiller unit that may be configured to chill fluids pumped therethrough to a particular temperature set point. The chilled fluid may then be circulated through one or more fluid flow lines or passages and through the cooling passages 114 that may, for example, be arranged so as to follow one or more flow paths within the pedestal 110 and proximate to the wafer support surface 112. The cooling passage(s) 114 may, for example, be arranged in spiral, serpentine, or other configuration so as to allow for distributed cooling of the wafer 108 across the wafer support surface 112. The pedestal cooling system 118 may, for example, be configured so as to be able to cool the wafer support surface 112, and, when present, the wafer 108, to a temperature within a first temperature range, e.g., within −30° C. to 20° C., e.g., −10° C.

The processing chamber 102 may also include one or more heaters 130, e.g., resistive cartridge heaters, that may be controlled so as to heat the processing chamber 102 to an elevated temperature with respect to the temperature of the pedestal 110, e.g., a temperature in the range of −40° C. to 110° C., e.g., 100° C.

The processing chamber 102 may also include a lift pin mechanism 120 having a plurality of lift pins 122 that may be moved between a first position relative to the pedestal 110 and a second position relative to the pedestal 110. In the first position, the lift pins 122 may not extend up past the wafer support surface 112, i.e., the lift pins 122 do not act to lift the wafer 108 off of the wafer support surface 112. In the second position, the lift pins extend beyond the wafer support surface 112, i.e., the tips of the lift pins 122 may contact the underside of the wafer 108, thereby supporting the wafer 108 over the wafer support surface 112 without the wafer 108 actually touching the wafer support surface 112. The lift pin mechanism 120 may include, for example, one or more linear actuators that may be configured to cause the lift pins 122 to move between at least the first position and the second position responsive to one or more inputs.

The processing chamber 102 may also include a gas distribution system 138 that may be configured to distribute process gases for a dry development process across the wafer 108. The gas distribution system 138, in this example, includes a showerhead 148 that is positioned above the wafer support surface 112. The showerhead 148 may have a faceplate 144 that has a plurality of outlets 142 that may distribute process gases from a showerhead plenum 149 that are provided to the showerhead plenum 149 via one or more inlets 140. The showerhead plenum 149 may be defined, for example, between the faceplate 144 and a backplate 146. In some implementations, the backplate 146 may, as depicted in FIG. 1, be connected with a top of the processing chamber 102 by a stem. Such a showerhead 148 may be referred to as a chandelier-type showerhead. In other implementations, the showerhead 148 may be integrated into the top of the processing chamber 102 so as to form part of the processing chamber 102 walls. Such a showerhead may be referred to as a flush-mount showerhead.

The gas distribution system 138 may be connected with, or may also include, a plurality of valves 150 (150a, . . . 150x-1, 150x, etc.) that may be used to control gas flow of process gas or gases from one or more gas sources 152 (152a, . . . 152x-1, 152x, etc.) to the one or more inlets 140 responsive to corresponding control signals or other input signals. During gas flow operations, one or more of the valves 150 may be controlled, e.g., by a controller (as discussed later herein) in order to cause gas from one or more of the gas sources to be flowed into the gas distribution system 138 and then out of the outlets 142 an into a region above the wafer support surface 112 of the pedestal 110.

The apparatus 100 may, in some implementations, further include an exhaust system 126 that includes an exhaust plenum 124 (an annular passage, in this example, that encircles a point centered beneath the wafer support surface 112) that is fluidically connected with the interior of the processing chamber by a one or more ports or openings, thereby allowing a pump 128 of the exhaust system 126 to draw a vacuum on the processing chamber 102 in order to evacuate gases from the processing chamber 102.

The apparatus 100 may also include, for example, a passage 106 that may connect the processing chamber 102 to, for example, a second chamber 104, e.g., a transfer module or other chamber. The passage 106 may include a gate valve 132 that may include a gate valve actuator 134 that may be used to controllably raise and lower a gate 136 that may be used to seal or open the passage 106 so as to either hermetically seal the processing chamber 102 from the second chamber 104 or allow the wafer 108 to be passed from the processing chamber 102 to the second chamber 104 along a path via the passage 106. It will be understood that the gate valve 132 may also be replaced with other hardware, e.g., a slit valve, sliding door, pivoting door, etc., that may allow the passage 106 to be sealed during wafer processing within the processing chamber 102 and opened for transfer of the wafer 108 between the processing chamber 102 and the second chamber 104. Regardless of the particular hardware used, such controllably openable/closable barriers that act to seal or unseal the processing chamber (or other chambers) may be referred to herein as “valve mechanisms” or the like. Such valve mechanisms may be transitionable between a first configuration, in which the passage is sealed by the valve mechanism so as to allow different pressure environments to exist on either side of the valve mechanism within the passage, and a second configuration, in which the passage is not sealed by the valve mechanism so as to allow a wafer (or similarly sized object), as well as any hardware used to move the wafer (such as an end effector of a wafer handling robot) to be moved through the passage and into or out of the processing chamber.

The apparatus 100 may also include a controller 156 that may include one or more memory devices 158 and one or more processors 160. The one or more memory devices 158 may store computer-executable instructions that, when executed by the one or more processors 160, cause the one or more processors 160 to cause various components, e.g., the valves 150, the gate valve 132, the heaters 130, the pedestal cooling system 118, the exhaust system 126, etc. to perform various operations consistent with the disclosure provided herein.

In the depicted example, the apparatus 100 also includes a plurality of light sources 162, which are, in this case, LEDs 166 mounted to a substrate 168. The substrate 168 may include electrical traces that allow the one or more light sources to be controllably illuminated. The light sources 162 are configured to direct light in a generally downward direction, e.g., towards the wafer support surface 112 (as represented by the wavy lines radiating outward from each light source 162. The processing chamber 102 may include one or more apertures that are sealed with one or more windows 164 that may be interposed between the light sources 162 and the wafer support surface 112. The one or more windows 164 may, for example, be made of optically transmissive silicon oxide (for example, quartz) or containing aluminum oxide (for example, sapphire) such that the light that is emanated by the one or more light sources 162 may generally pass therethrough with relatively little attenuation. For example, the one or more windows may be made from a material that is optically transmissive at the thickness used for the one or more windows to light at least having a wavelength or wavelengths in range between 400 nm to 490 nm, between 600 nm to 1300 nm, or between 400 nm to 490 nm and between 800 nm to 1300 nm. Optically transmissive, as the term is used herein, refers to optical transmittance of at least 60% or greater of the light in the wavelength range of interest. It will be understood that the material used for the one or more windows may also optionally include one or more dopants to, for example, modify various optical properties thereof or otherwise provide enhanced performance in one or more respects.

The showerhead 148 in FIG. 1 is, in this case, also made at least partially from an optically transmissive material such as described above, thereby allowing the radiation from the one or more light sources 162 to similarly pass through the showerhead 148 to reach the wafer support surface 112. While the entire showerhead 148 in this example need not be made of such optically transmissive material, at least a portion of the faceplate 144 and the backplate 146 may be made from such an optically transmissive material so as to allow the surface of the wafer 108 to be irradiated by the radiation emitted from the one or more light sources 162. In some implementations, the one or more light sources 162 and/or the window 164 may be configured such that the area illuminated by the one or more light sources is a circular area that is sized such that substantially the entire wafer 108 is able to be illuminated by the one or more light sources 162 while little or no direct light from the one or more light sources 162 is able to pass by the wafer 108 and illuminate, for example, the wafer support surface 112 or the pedestal 110 directly.

In such an apparatus, dry development processing may be performed after the wafer 108 has been introduced to the processing chamber 102 and placed upon the wafer support surface 112 and cooled to a temperature within the first temperature range by the pedestal cooling system 118. Once the wafer 108 has reached the temperature within the first temperature range, a set of one or more dry development processing gases may be caused to flow from the gas source(s) 152 and through the showerhead 148 via the inlet(s) 140 so as to exit the showerhead 148 via the outlets 142 and flow across the wafer 108. After steady state flow of the set of one or more dry development gases has occurred for a predetermined period of time or until a predetermined amount of dry development has occurred, the flow of the set of one or more gases through the showerhead 148 may be caused to cease. The one or more light sources 162 may then be caused to illuminate the wafer 108 in order to heat the wafer 108 to a temperature in a second temperature range in which the lower end of the second temperature range is higher than the upper end of the first temperature range. The second temperature range may, for example, be between 180° C. to 250° C., e.g., the temperature within the second temperature range may, for example, be −180° C.

After the wafer 108 has been heated to the temperature in the second temperature range, the one or more light sources 162 may be caused to maintain the wafer 108 at the temperature (or temperatures) within the second temperature range for a period of time during which the PDDB may be performed.

In some implementations, a purge gas or other inert gas, e.g., argon, nitrogen, etc. (an inert gas in this instance is to be understood to include not only noble gases but also nitrogen gas, which may be generally non-reactive to most gases used in dry development processing), may be flowed through the gas distribution system 138 and into the processing chamber 102 via the outlets 142 during at least part of the period of time in which the wafer 108 is illuminated by the one or more light sources 162. The exhaust system 126 may also be controlled so as to cause such purge gas flow to occur in conjunction with the evacuation of gas from the processing chamber 102 by the exhaust system 126, thereby allowing potential residual processing gases that are present within the processing chamber 102 to be evacuated from the processing chamber 102.

In some such implementations, the illumination of the wafer 108 by the one or more light sources 162 may be performed after the purge gas flow has been initiated. In some further such implementations, the molar density within the processing chamber 102 of the set of one or more processing gases used for the dry development process gas flow may be decreased to 10% or less of the molar density within the processing chamber 102 of the set of one or more processing gases during the dry development process gas flow. For example, after the dry development process has been completed, purge gas may be flowed into the processing chamber 102 such that the pressure within the processing chamber 102 is raised to, for example, at least 10× the pressure used during the dry development process. The process chamber 102 may then be pumped down to at least the pressure level used during the dry development process; this has the effect of diluting the one or more processing gases that may have remained in the chamber after the dry development process to a concentration of 10% or less of the molar density of those same gases during the dry development process. If desired, several such purge and pump cycles may be performed in order to further reduce the molar density of such gases. The purge gas flow may be intermittently or continuously applied during such operations.

The purge gas flow may be maintained at a particular flow rate or rates during a first period of time prior to the one or more light sources 162 being caused to illuminate the wafer 108; the first period of time may, for example, be predefined and based on an amount of time which has been shown to achieve the desired molar density reduction.

In some implementations, the one or more light sources 162 may also be caused to illuminate the wafer 108 prior to cooling by the pedestal cooling system 118 and the flow of the set of one or more dry development process gases thereacross. For example, the one or more light sources may be cause to illuminate the wafer 108 prior to flow of the set of one or more dry development process gases thereacross in order to heat the wafer to a temperature in a third temperature range, e.g., within 130° C. to 250° C., e.g., ˜200° C. The third temperature range, for example, may be a temperature range for a post-exposure bake (PEB) that may be performed after the wafer 108 has been exposed to EUV radiation but prior to the performance of the dry development process.

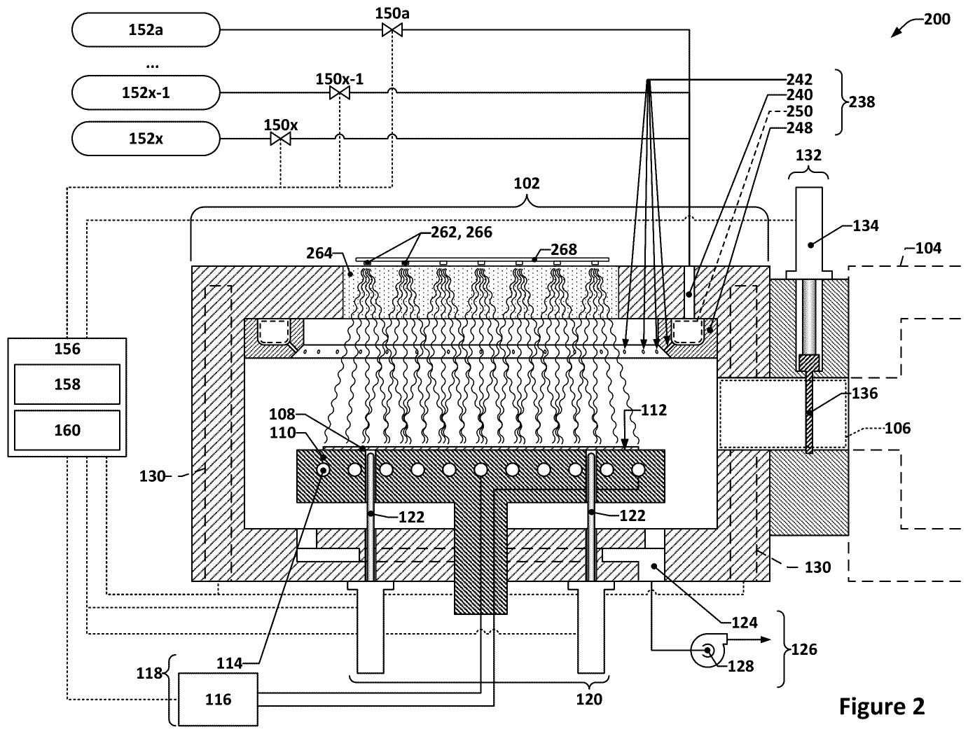

FIG. 2 depicts a similar apparatus 200 having components similar to that of apparatus 100. The apparatus 200 does not feature the gas distribution system 138 of the apparatus 100, however, and instead has gas distribution system 238, which includes a gas distributor 248 that has a plurality of outlets 242. The gas distributor 248 is, unlike the showerhead 148, annular in nature, generally encircling the wafer 108 when viewed from above. The outlets 242 may be arranged in a circular array about the center of the wafer 108 so as to direct processing gas radially inward, and downward towards the wafer support surface 112, from, for example, an annular gas distributor plenum 250 towards the center of the wafer 108. One or more inlets 240 may be provided that may allow gas from the gas source(s) 152 to be provided to the gas distributor 248.

A window 264 may be provided in an upper part of the processing chamber 102 and interposed between one or more light sources 262, which may be LEDs 266, and the wafer support surface 112. The LEDs 266 may be mounted to a substrate 268 that may include electrical traces that allow the one or more light sources 262 mounted thereto to be controllably illuminated.

Since the gas distributor 248 is annular in shape and has an opening in the middle underneath the window 264, the gas distributor 248 may be made of a material that is not necessarily optically transparent to the light from the one or more light sources 262.

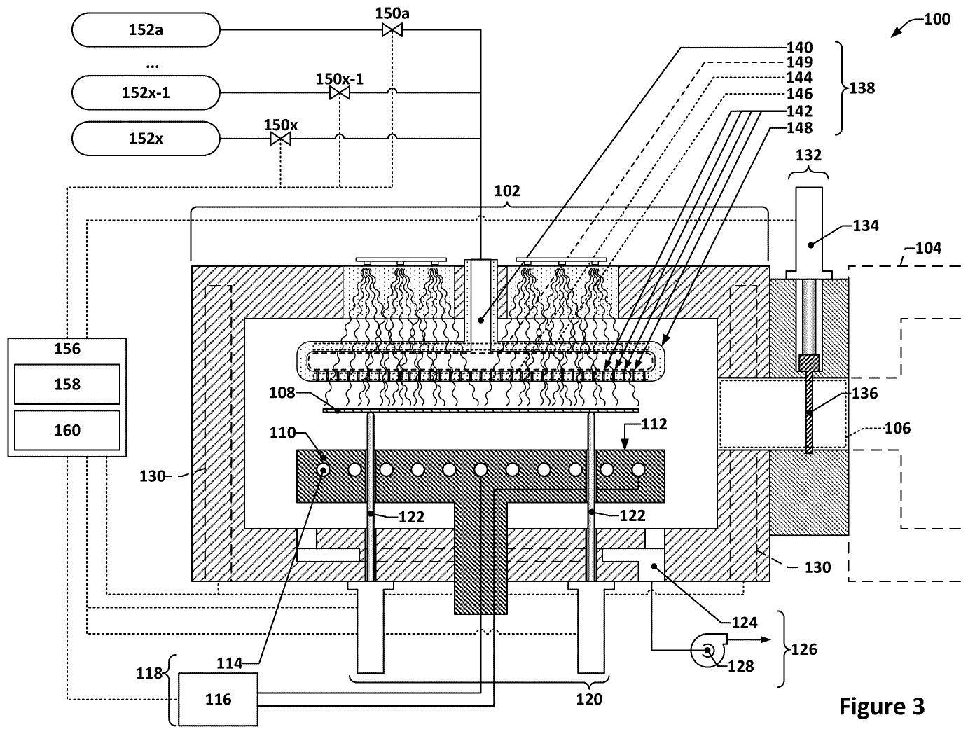

It will be appreciated that the apparatuses 100 and 200 may both be modified to work in a somewhat different manner that may allow for more efficient wafer heating and cooling, as shown in FIG. 3. In FIG. 3, the apparatus 100 is shown again, but with the wafer 108 elevated above the pedestal 110 and wafer support surface 112 by the lift pins 122, which have been actuated into the second position relative to the pedestal 110.

By lifting the wafer 108 so that it is no longer in thermally conductive contact with the wafer support surface 112 of the pedestal 110, heat that is provided to the wafer 108 while elevated is no longer able flow from the wafer 108 to the pedestal 110 via thermal conduction. In fact, the only thermally conductive contact between the wafer 108 and other solid objects in such circumstance is via the portions of the lift pins 122 that contact the underside of the wafer 108. The lift pins 122, due to their long, thin nature and the small area of the lift pin 122/wafer 108 contact patches, may provide a negligible amount of conductive heat transfer out of the wafer 108. This may allow the wafer 108 to be heated up by the one or more light sources 162 much more rapidly than would be the case were the wafer 108 to be subjected to similar illumination-based heating while resting directly on the wafer support surface 112. Moreover, by thermally decoupling the wafer 108 from the pedestal 110 during such illumination-based heating, such apparatuses 100 may also allow the wafer support surface 112 of the pedestal to be maintained at a much lower temperature, e.g., the temperature at which the dry development process is to be performed.

The use of lift pins to thermally decouple the wafer 108 from the pedestal 110 may be practiced in tandem with any illumination-based heating of the wafer 108 where the heating occurs within the processing chamber 102 and with the wafer 108 positioned, at least horizontally, over the wafer support surface 112. For example, if the wafer 108 is to be heated to perform a PEB, then the wafer 108 may be lifted clear of the wafer support surface 112 by the lift pins 122 (or alternatively, simply placed on the raised lift pins 122 without first touching the wafer support surface 112). Similarly, if the wafer 108 is to be heated to perform a PDDB, then the wafer 108 may be lifted clear of the wafer support surface 112 by the lift pins 122 after the set of one or more process gases for dry development processing have bene flowed across the wafer 108.

It will be apparent that thermally decoupling the wafer 108 from the wafer support surface 112 of the pedestal 110 not only allows the one or more light sources 162 to heat the wafer 108 much more rapidly, but also allows the pedestal cooling system 118 to cool the wafer 108 much more rapidly than if the wafer 108 were on the wafer support surface 112 during the radiative heating using the one or more light sources 162. In the latter case, heat from the radiative heating would transfer from the wafer 108 into the pedestal 110, thereby causing the pedestal 110 to potentially heat up and requiring the pedestal 110 to undergo additional cooling to overcome such heat build-up before it can cool the wafer 108 down. In contrast and as mentioned above, when the wafer 108 is heated while thermally decoupled from the wafer support surface 112 and the pedestal 110, this allows the pedestal cooling system 118 to maintain the wafer support surface 112 at the target temperature without having to drain away additional heat that may be provided during, for example, a PEB process. When the wafer 108 is lowered onto the wafer support surface at the conclusion of the PEB process, the only heat that the pedestal cooling system 118 needs to be able to remove is what little heat is contained within the wafer 108, e.g., ˜7.3 kJ for a wafer 108 made of silicon and having a 300 mm diameter and needing to be cooled from 180° C. to −10° C.

The use of lift pins 122 to thermally decouple the wafer 108 from the wafer support surface 112 and pedestal 110, it will be understood, may be practiced with any of the apparatuses discussed herein in which the wafer 108 may be subjected to radiative heating when in the processing chamber 102 and generally positioned over pedestal 110, regardless of the specific configuration.

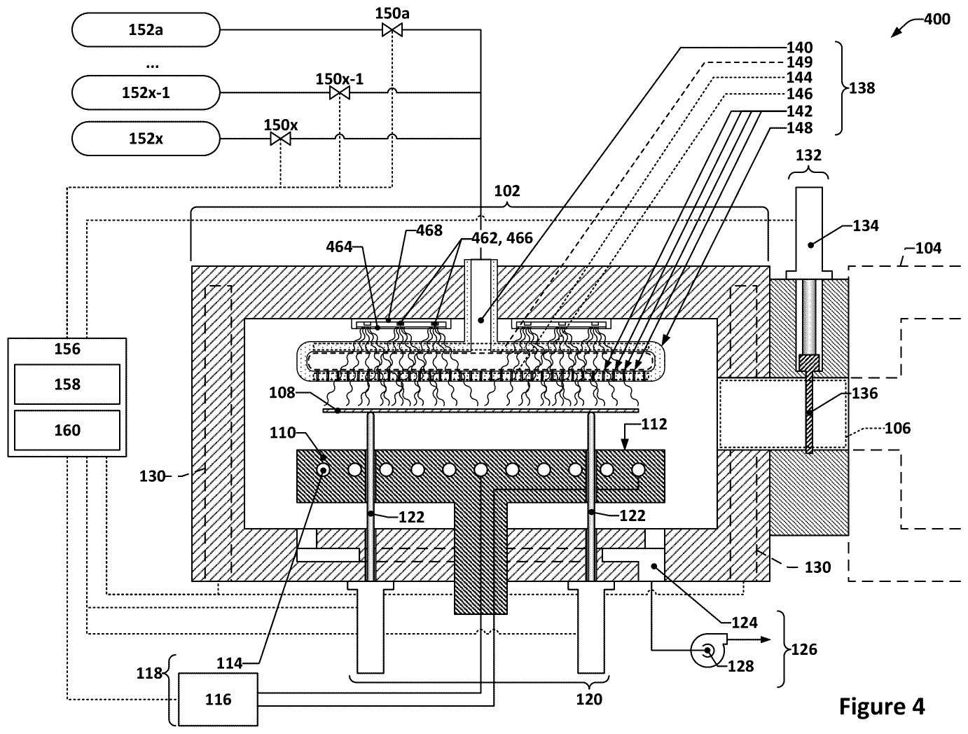

FIG. 4 depicts an example apparatus 400 that is similar in construction to the apparatus 100, except that the one or more light sources 462, which may be LEDs 466, are positioned within the processing chamber 102 instead of outside of the processing chamber 102. Such a configuration avoids the need for the inclusion of windows 164 within the walls or ceiling of the processing chamber 102. The one or more light sources 462, in this case, are mounted to a substrate or substrates 468, e.g., that have electrically conductive traces that permit the one or more light sources to be powered in order to provide radiative heating of the wafer 108. The substrate(s) 468 and one or more light sources 462 may optionally be covered by one or more windows 464 that may act to shield the one or more light sources 462 and/or the substrate(s) 468 from potentially damaging exposure to gases within the processing chamber 102. In other implementations, the one or more light sources 462 may each have individual windows 464, each of which may shield an individual light source 462. In such implementations, the windows 464 may, in some instances, be part of, for example, an LED package. This may be the case with any of the implementations discussed herein in which the light sources are located within the processing chamber and/or other chamber and/or passage between such chambers.

In FIG. 4, the one or more light sources are positioned directly above the wafer support surface 112 such that light from the one or more light sources may be directed generally downward, through the showerhead 148 (which, as discussed above with respect to FIG. 1, may be made at least partially of optically transmissive materials, e.g., materials such as silicon oxide or aluminum oxide or variations thereof), and onto the wafer 108.

In this particular example, the wafer 108 is shown in a raised position on the lift pins 122, with the one or more light sources 462 emitting light (as represented by the wavy lines emitted from each light source 462) onto the wafer 108 to perform, for example, a PDDB or PEB process.

In addition to moving the one or more light sources to be within the processing chamber 102, some implementations may include multiple light sources that are distributed across the underside of the showerhead (if present).

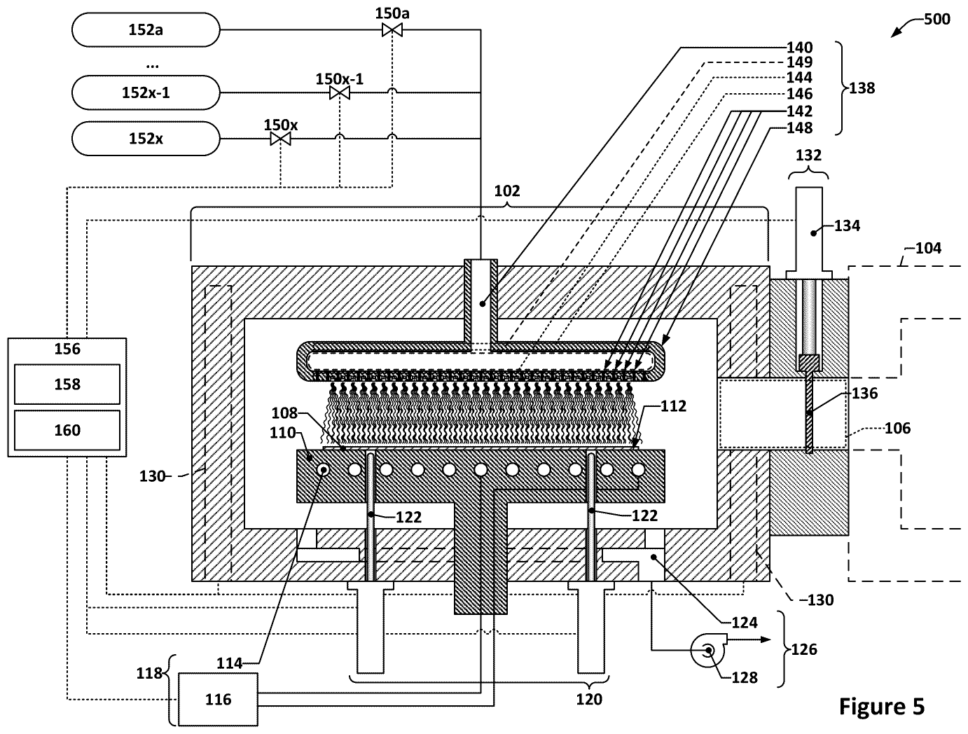

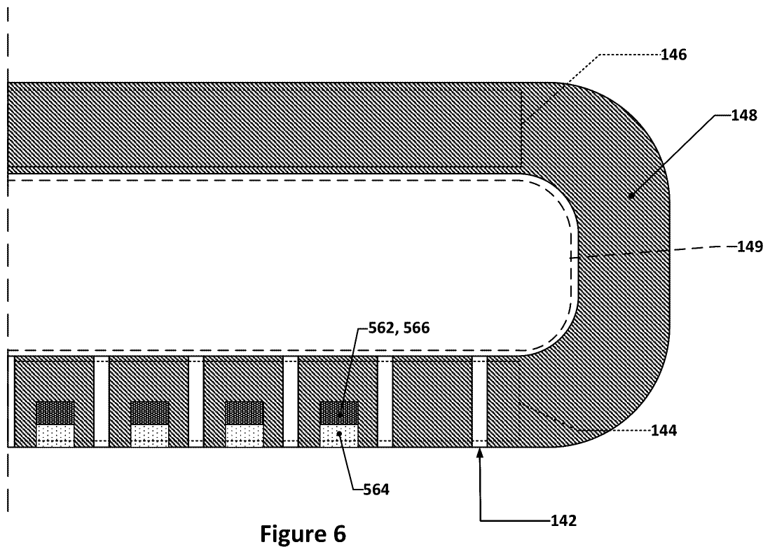

FIG. 5 depicts an example apparatus 500 that is similar to that of FIG. 4, except that the one or more light sources 462 have been replaced with a plurality of light sources 562 that are distributed across the underside of the faceplate 144 of the showerhead 148. While not visible in FIG. 5 due to scale considerations, FIG. 6 depicts a detail view of an outer peripheral region of the showerhead 148. Visible in FIG. 6 are the light sources 562, which may be LEDs 566, that are positioned along the underside of the faceplate 144 and interspersed between outlets 542 of the showerhead 148. The light sources 162 may be covered by windows 564, which may protect the light sources 162 (and/or the substrate(s) (not shown) on which they are mounted) from exposure to the gases that may be flowed out of the outlets 142 during dry development processing.

It will be understood that the outlets 142 and the one or more light sources 562 may not be completely coextensive with one another. For example, the outlets 142 may be distributed across a first portion of the faceplate 144 and the light sources 562 may be distributed or evenly distributed across a second portion of the faceplate 144 that is smaller than the first portion. The first portion and the second portion may, for example, be centered on one another and each may be circular, annular, or radially symmetric about their center points.

Such an arrangement may provide a more efficient heating mechanism than the implementations discussed earlier, as the light sources 562 are positioned such that the light emanated therefrom is directly incident on the wafer 108 and does not need to pass through the showerhead 148. Moreover, the showerhead 148 in such an implementation does not need to be at least partially optically transmissive and may thus be made of less expensive and more easily machined materials than, for example, silicon oxide or aluminum oxide.

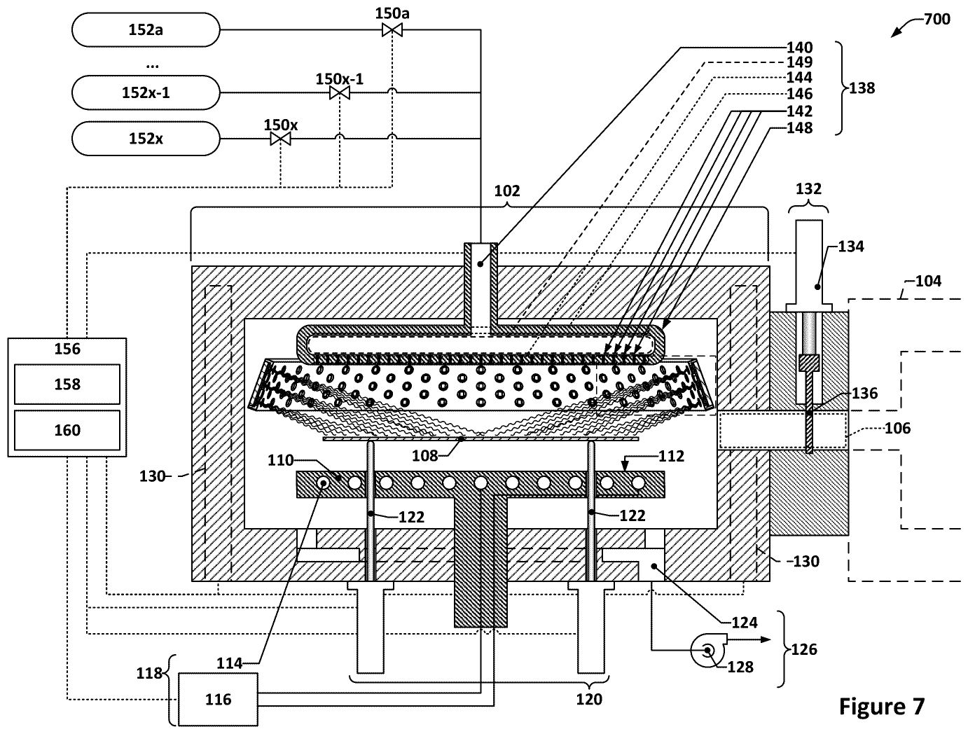

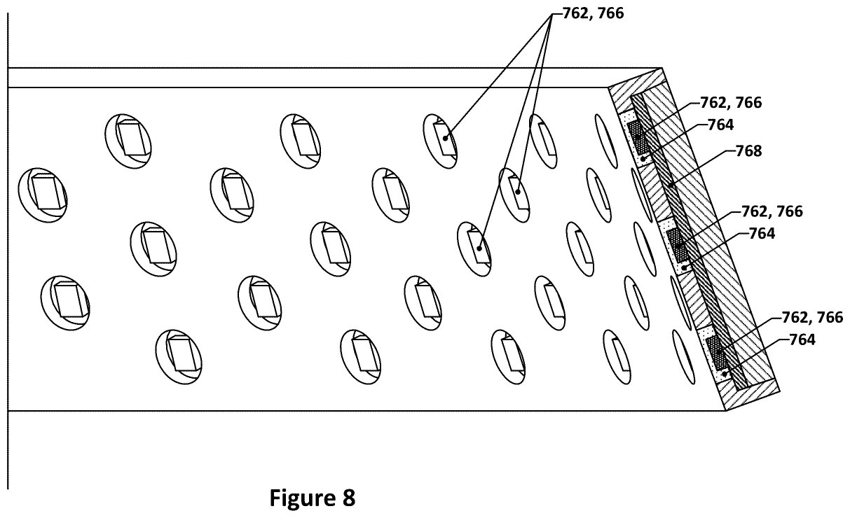

FIG. 7 depicts another apparatus 700 that is similar to the apparatus 500 except that the one or more light sources are arranged within the processing chamber 102 so as to form several circular arrays centered on the showerhead 148. FIG. 8 depicts a detail view of a portion of the light sources within the dashed-line rectangle shown in FIG. 7. The light sources 762, which are LEDs in this example, may be mounted to a substrate 768 and may be covered by windows 764 that may protect the light sources 762 and the substrate 768 from the dry development gases that may be within the processing chamber 102. The light sources 762 may be oriented so as to emit light predominantly along axes that are directed towards a center axis of the wafer support surface 112 (i.e., towards where the center axis of the wafer 108 would be when the wafer 108 is present) and downward towards where the wafer 108 will be during radiative heating. The light from the light sources 762 may strike the wafer 108 at a relatively shallow angle that allows the light from the light sources to illuminate the entire wafer 108, including the center portion thereof.

The substrate 768 may, for example, be a flexible printed circuit or similar material that may be formed into a conical frustum shape in order to orient the light sources 762 mounted thereupon as described above. Alternatively, the substrate may be replaced with a circular array of flat, rigid printed circuit boards arranged so as to form, in effect, a faceted conical frustum shape, each facet of which may have one or more light sources 762 mounted thereto. Each such facet may be oriented such that the normal to each facet is oriented radially inward towards the center axis of the wafer support surface 112 and downward towards the wafer support surface 112.

Such arrangements allow for the use of a showerhead 148 that does not include optically transmissive portions, while also allowing the showerhead 148 and the light sources 762 to be provided as separate components so that the construction of the showerhead 148 may be simplified.

It will be understood that in all of the implementations discussed above, the wafer 108 may, during radiative heating operations, be thermally decoupled from the pedestal 110 by lifting the wafer 108 off of the wafer support surface 112 using the lift pins 122 (or other system for lifting the wafer 108 off of the wafer support surface 112).

In addition to variants discussed above in which radiative heating of the wafer occurs while the wafer 108 is still within the processing chamber 102, e.g., in the same horizontal position it was in (or will be in) during dry development processing, some implementations may be configured to provide radiative heating of the wafer 108 either during transit into/out of the processing chamber 102 or in a separate chamber from the processing chamber 102.

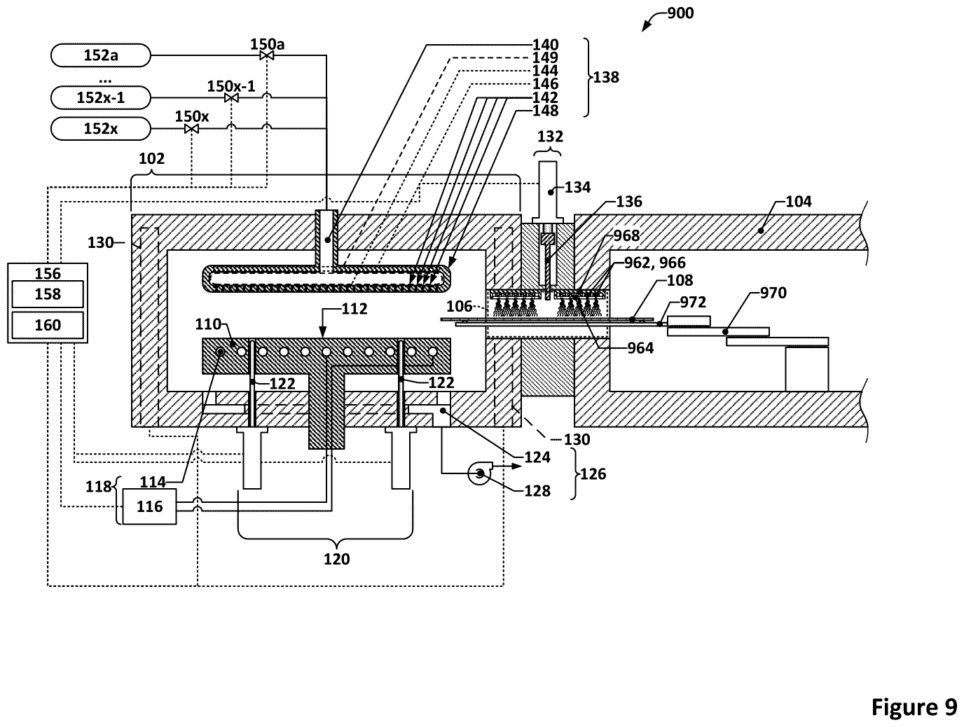

For example, FIG. 9 depicts an example apparatus 900 which includes the processing chamber 102. As discussed previously, the processing chamber 102 (which may also be thought of as a “first chamber”) may be connected, via the passage 106, to the second chamber 104, which is shown in FIG. 9 in more detail. The second chamber 104, in this example, is a vacuum transfer module. A vacuum transfer module is a chamber that is typically much larger than a processing chamber and which serves as a hub to which multiple processing chambers are attached. Vacuum transfer modules typically include one or more wafer handling robots or other mechanisms that allow wafers to be placed in, and withdrawn from, the processing chambers attached thereto. The interfaces between the vacuum transfer module and the processing chambers attached thereto are typically equipped with some form of gate valve, slit valve, or other controllably openable/closable barrier that allows the environment of the processing chamber to be sealed off from the vacuum transfer module during wafer processing operations. Vacuum transfer modules are typically connected with vacuum pump systems that allow the vacuum transfer modules to be operated at sub-atmospheric pressure conditions.

In FIG. 9, the second chamber 104, being a vacuum transfer module, is shown with a wafer handling robot 970 that may include one or more articulated robot arm links that may be controlled so as to cause an end effector 972 of the wafer handling robot 970 to be extended or retracted, for example, along one or more axes and rotated about one or more axes. In FIG. 9, the gate valve 132 is shown in an open state and the wafer 108 is shown as being supported by the end effector 972 of the wafer handling robot 970 as the wafer 108 transits through the passage 106. The wafer 108 may be in such a configuration either during placement into the processing chamber 102 prior to performance of the dry development process or removal from the processing chamber 102 after the dry development process has completed.

As can be seen in FIG. 9, one or more light sources 962 are provided within the passage 106 so as to illuminate the wafer 108 during its transit through the passage 106. The banks of light sources 962, in this example, are mounted to (or part of) the ceiling or top interior surface of the passage 906, but may alternatively be mounted to, or extend into, the processing chamber 102 and/or the second chamber 104. In this example, there are two banks of light sources 962, one on either side of the gate valve 132. Each bank of light sources may be generally elongate in nature, e.g., extending across the passage 106 in a direction generally transverse to the direction along which the wafer 108 is moved during transit through the passage 106, thereby illuminating the wafer 108 with a generally elongate illumination area, e.g., similar to a line scanner. The long axis of each bank of light sources may, for example, be selected such that the width of the illumination area transverse to the direction of travel of the wafer 108 in a reference plane that is coincident with the wafer 108 when the wafer 108 is being transported through the passage 106 is at least as large as the diameter (D) of the wafer 108.

It will be understood that while FIG. 9 depicts two banks of light sources 962, each positioned proximate to an opposite side of the gate valve 132, other implementations may feature such light sources proximate to one side of the gate valve 132 or the other, but not to both sides of the gate valve 132.

When the wafer 108 is moved by the wafer handling robot 970 through the passage 106, the light sources 962 may be caused to illuminate the wafer 108 to radiatively heat the wafer 108. As end effector 972 of the wafer handling robot 970 will typically only contact the wafer 108 very minimally, e.g., via three or four small pads on the underside or three or four short regions along the wafer's outer edge, the amount of heat transfer from the wafer 108 to the end effector 972 via thermal conduction may, similar to when the wafer 108 is supported on the lift pins 122, be relatively small, thereby allowing for most of the heat that is transferred to the wafer 108 by way of illumination by the light sources 962 to be retained within the wafer 108 in order to more rapidly heat the wafer 108.

In some implementations, the wafer handling robot 970 may be caused, e.g., by the controller 156, to move the wafer 108 at a reduced speed while the wafer 108 is within the area illuminated by the one or more light sources 962 as compared with when the wafer 108 is in positions not illuminated by the one or more light sources 962. In some further or alternative such implementations, the light sources 962 for a bank of light sources may include subsets of light sources 962 that may be independently turned on and off based on the position of the end effector 972 and wafer handling robot 970 at any given point in time so as to reduce the amount of light that is emitted but does not contribute significantly to radiative heating of the wafer 108. For example, if the light sources 962 in a bank of light sources 962 are arranged in a single line in a direction transverse to the direction of travel of the wafer 108, then when the wafer 108 starts to pass beneath the light sources 962, the controller 156 may cause only the light source or sources 962 in the bank of light sources 962 that are closest to the wafer center to turn on—the remaining light sources 962 in the bank of light sources 962 may be kept in an off state. As the wafer 108 continues to move through the passage 106, additional light sources 962 in the bank of light sources 962 may be turned on, e.g., successive innermost pairs of the “off” light sources 962 bracketing the “on” light sources 962 may be turned on as the wafer 108 transits beneath the bank of light sources 962 and more and more of the surface area of the wafer 108 is present within the illumination area of the light sources 962. The process may be reversed once the wafer 108 reaches a point where the wafer center is directly beneath the bank of light sources 962, with successive outermost pairs of “on” light sources 962 being turned off as the wafer 108 continues its movement and those light sources 962 no longer effectively contribute to illuminating the wafer 108 (or such that the illumination that they provide is largely illuminating objects other than the wafer 108, for example).

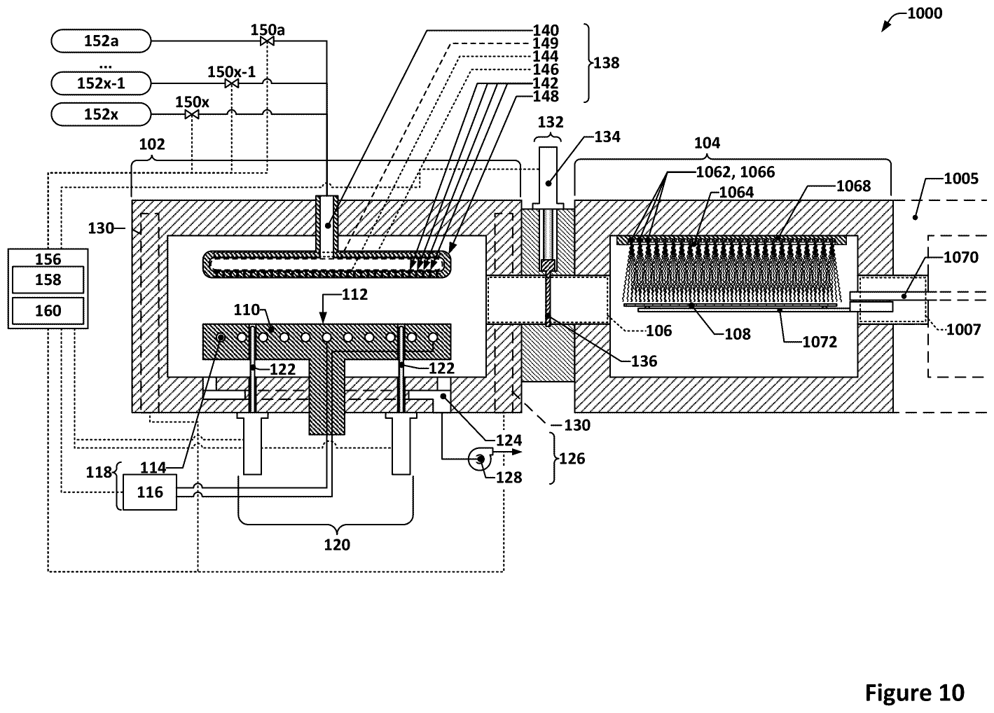

In yet another implementation, a radiative heating system with one or more light sources may be provided within an entirely separate chamber from the processing chamber. FIG. 10 depicts an implementation in which the processing chamber 102 is connected via the passage 106 to the second chamber 102. In this example, the second chamber 104 may be, for example, a vestibule chamber that is interposed between the processing chamber 102 and a third chamber 105, e.g., a vacuum transfer module chamber. The third chamber 105 may, for example, be connected with the second chamber 104 by way of a second passage 1007. The second passage 1007 may, for example, optionally be equipped with a valve mechanism similar, for example, to the gate valve 132 (although this is not shown) to allow the second chamber 104 to be sealed off from the third chamber 1005.

The second chamber 104 may be simpler in construction as compared with the processing chamber 102, and may, for example, simply have an internal volume that is larger than a cylindrical reference volume having the same diameter as the wafer.

The second chamber 104 may include within it one or more light sources 1062 that may be mounted so as to illuminate the wafer 108 while the wafer 108 is positioned therewithin. As shown, the one or more light sources 1062 are mounted to a substrate 1068 that is mounted to an innermost surface of the second chamber 104, e.g., the top inside surface of the second chamber 104, so as to illuminate the wafer 108 positioned therebeneath. In an alternate implementation, the one or more light sources may be mounted externally to the second chamber 104 and a window may be provided in the top surface of the second chamber 104 to allow for illumination of the wafer 108 by the one or more light sources 962. The one or more light sources may, in some implementations, be arranged so as to produce a circular illumination area in a reference plane that is coincident with the wafer when the wafer is being illuminated by the one or more light sources that is the same size as the wafer.

The wafer 108 may be supported within the second chamber 104 by, for example, an end effector 1072 of a wafer handling robot 1070 located, for example, within the second chamber 104 or, as shown in FIG. 10, within the third chamber 1005 but capable of reaching into both the processing chamber 102 and the second chamber 104. Alternatively, the second chamber 104 may be equipped with, for example, structures similar to the lift pins 122 such that the wafer 108 may be placed thereupon and supported thereby during radiative heating by the light sources 1062 and then later removed by, for example, the wafer handling robot 1070 or a similar apparatus.

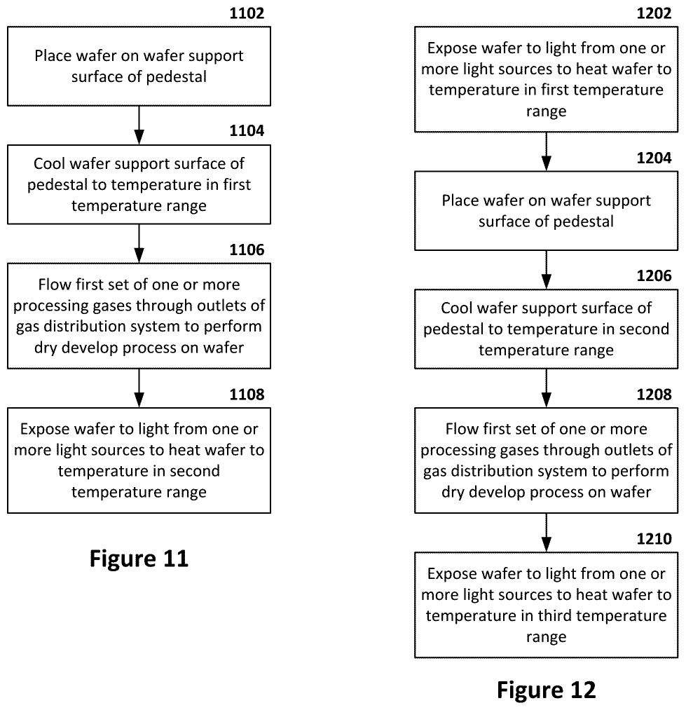

The above discussion of various apparatus implementations has provided some insight as to the manner of use of the various implementations discussed. FIGS. 11 through 16 are discussed below to provide further details regarding potential usage of the apparatuses discussed above. While not described below, the techniques of FIGS. 11 through 15 may generally also involve determining, in some fashion, that a wafer to be subjected to a dry development process is present within the process chamber. Such a determination may be made, for example, responsive to state information for various pieces of equipment, e.g., if a wafer handling robot has been commanded to place the wafer into the processing chamber and then provides feedback that indicates that it has performed operations necessary to do so, then a determination may be made that the wafer is within the processing chamber. In other implementations, a more explicit determination may be made, e.g., using sensor data that indicates when a wafer is positioned in a particular position or positions within the processing chamber. Such determinations may also be viewed as determinations that a wafer that is present within the processing chamber is to be prepared for undergoing a dry development process (e.g., by cooling the wafer to a low temperature, e.g., such as discussed earlier, and optionally subjecting the wafer to a PEB prior to such cooling)

FIG. 11 depicts a flow chart of a technique for performing a dry development process followed by a post-dry-development bake operation. In FIG. 11, the technique begins in block 1102, in which a wafer to be processed is placed on a wafer support surface of a pedestal within a dry development processing chamber, such as one of the processing chambers discussed above with respect to FIGS. 1 through 8. The wafer to be processed is a wafer having a photopatterned metal-containing photoresist that is to be subjected to the dry development process.

In block 1104, the wafer may be cooled down to a temperature within a first temperature range by a pedestal cooling system that may be configured to, for example, maintain the temperature of at least a portion of the pedestal having the wafer support surface to be within the first temperature range. The first temperature range, for example, may be between −30° C. and 20° C., e.g., allowing the wafer to be cooled, for example, to a temperature of approximately −10° C.

Once the wafer reaches the desired temperature in the first temperature range, the dry development process may be performed in block 1106, e.g., by flowing a first set of processing gases through a gas distribution system of the processing chamber and across the wafer. The determination of when the wafer reaches the desired temperature may be made in potentially a variety of different ways, e.g., an open-loop determination based solely on the amount of time that the wafer remains resident on the pedestal, a closed-loop determination that uses data from a temperature sensor in the pedestal to estimate the wafer temperature or data from a remote temperature sensor, e.g., such as a pyrometer, that may be used to measure the temperature of the wafer directly, etc.

The first set of processing gases may be flowed across the wafer for a duration of time and under flow conditions that may be tailored to a particular dry development process, e.g., according to a process recipe.

Once the dry development process has completed, the wafer may be subjected to radiative heating in block 1108, e.g., through exposure to radiation emitted from one or more light sources such as those discussed above. The wafer may, for example, be radiatively heated to a temperature within a second temperature range between, for example, 180° C. and 250° C., e.g., to approximately 180° C. The wafer may be held at this elevated temperature for a period of time, e.g., up to 4, 5, 6, 7, 8, 9, or 10 minutes, sufficient to drive out most or all of the volatile halides that may be present on the surfaces of the wafer.

FIG. 12 depicts a flow diagram of another technique for performing a dry development process followed by a post-dry-development bake operation. In FIG. 12, the technique begins in block 1202, in which a wafer to be processed is radiatively heated by exposure to light from one or more light sources in order to heat the wafer to a temperature in a first temperature range between 130° C. and 250° C., e.g., approximately 200° C. The wafer to be processed is a wafer having a photopatterned metal-containing photoresist that is to be subjected to the dry development process. The wafer may be held at such a temperature for a predetermined period of time in order to perform a post-exposure bake (PEB). The PEB may cause cleaved metal bonds, e.g., tin bonds in a tin-based alkoxy resist, to convert to metal-oxygen, e.g., tin-oxygen, bonds to form a material that is stoichiometrically close to a metal-oxide, e.g., tin-oxide, in areas of the wafer that were previously exposed to EUV radiation during photopatterning.

Once the PEB has completed, the technique may proceed to block 1204, in which the wafer, if not already present on a wafer support surface of a pedestal within the processing chamber, may be placed on the wafer support surface of the pedestal. For example, during block 1202, the wafer may be supported by lift pins (which may be in, for example, the second position) above the wafer support surface to thermally decouple the wafer from the wafer support surface and the pedestal. At the conclusion of block 1202, the wafer may be lowered onto the wafer support surface, thereby placing the wafer in thermally conductive contact with the wafer support surface and the pedestal. It will be understood that block 1202, i.e., the PEB, or a similar operation may be optionally performed at the start of any of the techniques 11 through 15.

In block 1206, the wafer support surface may be maintained at a temperature within a second temperature range between −30° C. and 20° C., e.g., approximately −10° C., in order to cool the wafer to a similar temperature in preparation for performing the dry development process.

Once the wafer reaches the desired temperature within the second temperature range, the technique may proceed to block 1208, in which a first set of processing gases may be flowed through a gas distribution system of the processing chamber and across the wafer. As in the technique of FIG. 11, the determination of when the wafer reaches the desired temperature may be made in potentially a variety of different ways, e.g., an open-loop determination based solely on the amount of time that the wafer remains resident on the pedestal, a closed-loop determination that uses data from a temperature sensor in the pedestal to estimate the wafer temperature or data from a remote temperature sensor, e.g., such as a pyrometer, that may be used to measure the temperature of the wafer directly, etc.

The first set of processing gases may be flowed across the wafer for a duration of time and under flow conditions that may be tailored to a particular dry development process, e.g., according to a process recipe.

Once the dry development process has completed, the wafer may be subjected to radiative heating in block 1210, e.g., through exposure to radiation emitted from the one or more light sources. The wafer may, for example, be radiatively heated to a temperature within a third temperature range between, for example, 180° C. and 250° C., e.g., to approximately 180° C. The wafer may be held at this elevated temperature for a period of time, e.g., several minutes (similar to as discussed above), sufficient to drive out most or all of the volatile halides that may be present on the surfaces of the wafer.

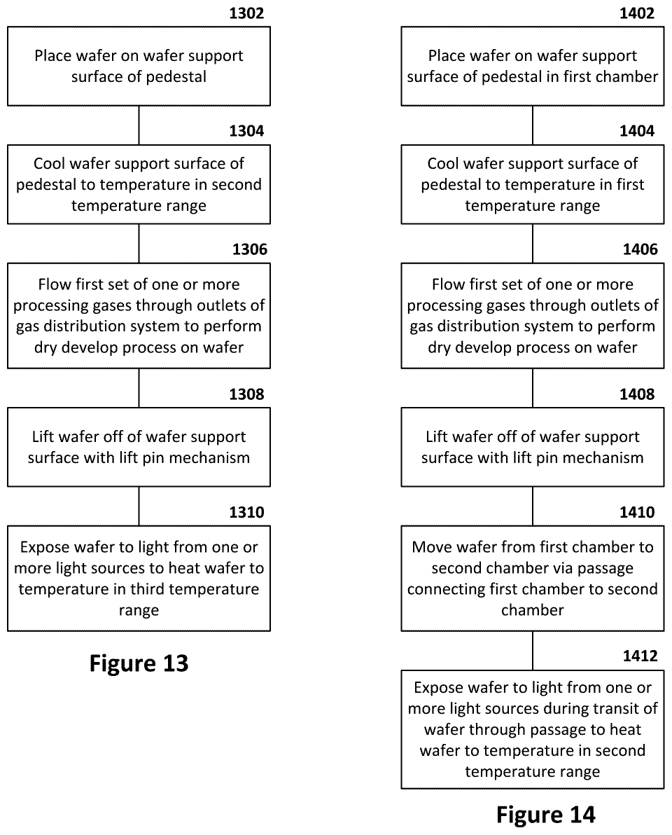

FIG. 13 depicts a flow diagram of another technique for performing a dry development process followed by a post-dry-development bake operation. In FIG. 13, the technique begins in block 1302, in which, as in the other techniques discussed above, a wafer to be processed is placed upon the wafer support surface of a pedestal in a dry development processing chamber. The wafer to be processed is a wafer having a photopatterned metal-containing photoresist that is to be subjected to the dry development process. As noted above, an optional PEB may be performed on the wafer prior to placement on the pedestal, although this is not explicitly shown in FIG. 13.

In block 1304, the wafer may be cooled to a temperature within a first temperature range between −30° C. and 20° C., e.g., approximately −10° C., in order to prepare the wafer for the dry development process. Such cooling may, for example, be performed using the pedestal cooling system to cool the pedestal and thus the wafer support surface and the wafer in thermally conductive contact therewith.

In block 1306, a first set of processing gases may be flowed through a gas distribution system of the processing chamber and across the wafer in order to perform a dry development operation on the wafer.

At the conclusion of the dry development operation, block 1308 may be performed to lift the wafer off of the pedestal using, for example, lift pins provided in the apparatus. Once the wafer is thermally decoupled from the pedestal, the wafer may then be exposed to radiative heating from one or more light sources in block 1310 in order to heat the wafer to a temperature in a second temperature range between 180° C. and 250° C., e.g., approximately 180° C., in order to perform a post-dry-development bake to drive out any resident volatile halides that may remain after the dry development operation.

After the wafer has been heated to the temperature in the second temperature range for, for example, a predetermined period of time, the wafer may then be removed from the processing chamber in order to perform further processing.

FIG. 14 depicts a flow diagram of another technique for performing a dry development process followed by a post-dry-development bake operation. Whereas the techniques of FIGS. 11 through 13 may be practiced in, for example, apparatuses such as apparatuses 100 through 7, the technique of FIG. 14 may be practiced, for example, in apparatuses such as the apparatus 900.

The technique of FIG. 14 may begin in block 1402, in which, as in the other techniques discussed above, a wafer to be processed is placed upon the wafer support surface of a pedestal in a dry development processing chamber. The wafer to be processed is a wafer having a photopatterned metal-containing photoresist that is to be subjected to the dry development process. As noted above, an optional PEB may be performed on the wafer prior to placement on the pedestal, although this is not explicitly shown in FIG. 14.

In block 1404, the wafer may be cooled to a temperature within a first temperature range between −30° C. and 20° C., e.g., approximately −10° C., in order to prepare the wafer for the dry development process. Such cooling may, for example, be performed using the pedestal cooling system to cool the pedestal and thus the wafer support surface and the wafer in thermally conductive contact therewith.

In block 1406, a first set of processing gases may be flowed through a gas distribution system of the processing chamber and across the wafer in order to perform a dry development operation on the wafer.

At the conclusion of the dry development operation, block 1408 may be performed to lift the wafer off of the pedestal using, for example, lift pins provided in the apparatus. The wafer may then, in block 1410, be moved from the processing chamber and into a passage that connects the processing chamber with an adjacent chamber, e.g., a vacuum transfer module. Such wafer movement may be performed by a wafer handling robot that may be located within the adjacent chamber and which may be controlled so as to reach into the processing chamber and lift the wafer off of the lift pins with an end effector. The wafer handling robot may then be controlled so as to retract the end effector, and the wafer supported thereby, from the processing chamber and through the passage.

In block 1412, the wafer may be subjected to radiative heating through illumination by one or more light sources that may be positioned above the wafer within the passage. In some implementations, during the transit of the wafer through the passage and the illumination provided by the one or more light sources, the wafer handling robot may be controlled so as to move at a slower speed when transiting the wafer through the passage so as to provide additional time for the wafer to be heated (or held at elevated temperature) in order to more thoroughly remove any volatile halides that may be resident thereupon. The radiative heating provided to the wafer by the one or more light sources may, for example, heat the wafer to a temperature in a second temperature range between 180° C. and 250° C., e.g., approximately 180° C., in order to perform a post-dry-development bake.

It will be understood that, in some implementations, during all or part of blocks 1408 and 1410, an exhaust system of the apparatus that is configured to evacuate gas from the processing chamber may be caused to operate so as to draw a vacuum or partial vacuum on the processing chamber so as to cause the pressure within the processing chamber to be lower than the pressure in the adjacent chamber, thereby causing volatile halides (or other substances) that may outgas from the wafer due to the radiative heating, to be drawn into the processing chamber and into the exhaust system for disposal. In some such implementations, if the adjacent chamber is also connected with a corresponding exhaust system, the exhaust system of the adjacent chamber may also be controlled so as to not draw a competing vacuum that results in the adjacent chamber having a lower pressure than the processing chamber.

As the processing chamber may already be configured to handle and dispose of such byproducts that may develop during dry development processing, such an implementation allows such byproducts to be handled without potentially requiring additional, redundant hardware for the adjacent chamber.

After the wafer has been heated to the temperature in the second temperature range for, for example, a predetermined period of time, the wafer may then be removed from the processing chamber in order to perform further processing.

If a PEB is to be performed in the technique of FIG. 14, similar operations to those in blocks 1410 and 1412 may be performed on the wafer as the wafer transits into the processing chamber via the passage. Similarly, in some implementations, the exhaust system may be controlled in a manner similar to the above to draw potential byproducts of the PEB into the exhaust system of the processing chamber during the PEB.

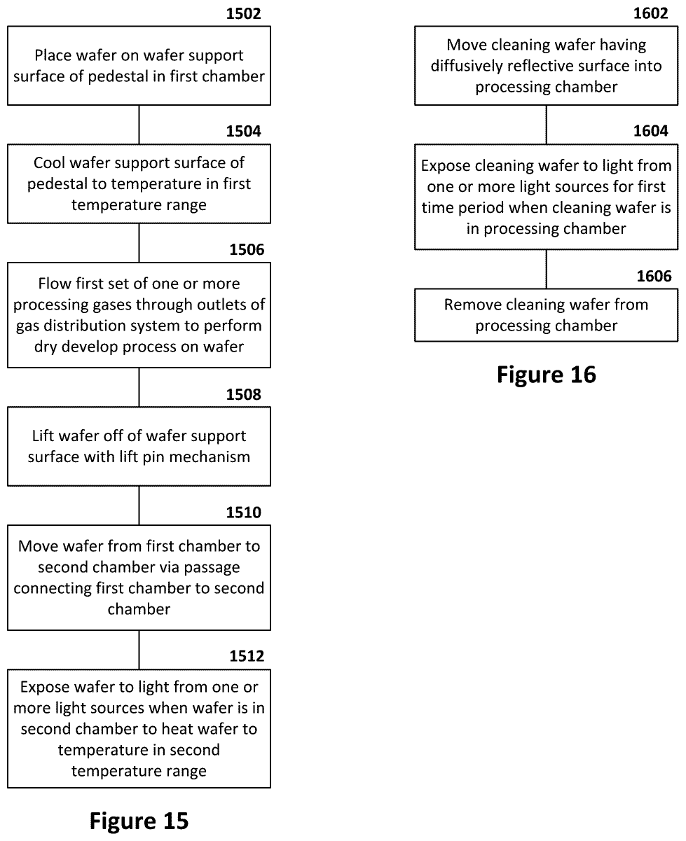

FIG. 15 depicts a flow diagram of another technique for performing a dry development process followed by a post-dry-development bake operation. As noted earlier, while the techniques of FIGS. 11 through 13 may be practiced in, for example, apparatuses such as the apparatuses 100 through 7, and the technique of FIG. 14 may be practiced in apparatuses such as the apparatus 900, the technique of FIG. 15 may be practiced, for example, in apparatuses such as the apparatus 1000.

The technique of FIG. 15 may begin in block 1502, in which, as in the other techniques discussed above, a wafer to be processed is placed upon the wafer support surface of a pedestal in a dry development processing chamber. The wafer to be processed is a wafer having a photopatterned metal-containing photoresist that is to be subjected to the dry development process. As noted above, an optional PEB may be performed on the wafer prior to placement on the pedestal, although this is not explicitly shown in FIG. 15.

In block 1504, the wafer may be cooled to a temperature within a first temperature range between −30° C. and 20° C., e.g., approximately −10° C., in order to prepare the wafer for the dry development process. Such cooling may, for example, be performed using the pedestal cooling system to cool the pedestal and thus the wafer support surface and the wafer in thermally conductive contact therewith.

In block 1506, a first set of processing gases may be flowed through a gas distribution system of the processing chamber and across the wafer in order to perform a dry development operation on the wafer.

At the conclusion of the dry development operation, block 1508 may be performed to lift the wafer off of the pedestal using, for example, lift pins provided in the apparatus. The wafer may then, in block 1510, be moved from the processing chamber and into a passage that connects the processing chamber with an adjacent chamber, e.g., a post-dry-development bake chamber. Such wafer movement may be performed by a wafer handling robot that may be located within the adjacent chamber or another chamber, such as a vacuum transfer module, that the second chamber may be connected to. The wafer handling robot may be controlled so as to reach into the processing chamber and lift the wafer off of the lift pins with an end effector. The wafer handling robot may then be controlled so as to retract the end effector, and the wafer supported thereby, from the processing chamber, through the passage, and into the second chamber.

Once the wafer is within the second chamber, the wafer may be subjected to radiative heating in block 1512 through illumination by one or more light sources that may be positioned above the wafer within the second chamber. In some implementations, the wafer may be placed on a support structure within the second chamber. Such a support structure may, for example, be similar to the lift pins used in the processing chamber, e.g., having minimal contact with the wafer and thus providing for very little or negligible heat loss from the wafer during radiative heating.

The radiative heating provided to the wafer by the one or more light sources may, for example, heat the wafer to a temperature in a second temperature range between 180° C. and 250° C., e.g., approximately 180° C., in order to perform a post-dry-development bake.

After the wafer has been heated to the temperature in the second temperature range for, for example, a predetermined period of time, the wafer may then be removed from the second chamber in order to perform further processing.

If a PEB is to be performed in the technique of FIG. 15, an operation similar to that in block 1512 may be performed while the wafer is within the second chamber as it transits through the second chamber to the first chamber prior to performance of blocks 1502 through 1510. Similarly, in some implementations, the exhaust system may be controlled in a manner similar to the above to draw potential byproducts of the PEB into the exhaust system of the processing chamber during the PEB.

In some implementations of the technique of FIG. 15, an exhaust system of the processing chamber may be operated so as to cause the pressure within the processing chamber to be less than the pressure within the second chamber; when the passage between the processing chamber and the second chamber is left open while such a pressure differential exists, this may act to draw any byproducts that may be driven out of the wafer through the radiative heating in block 1512 (or similar heating performed prior to blocks 1502 through 1510 to perform a PEB) into the exhaust system for proper disposal.

Apparatuses such as apparatuses 100 through 700 may also be specially configured to perform chamber cleaning operations on the processing chamber 102 using the one or more light sources. FIG. 16 depicts a flow chart of an example such cleaning process.

In block 1602, a cleaning wafer may be placed within a processing chamber. The cleaning wafer may be manually placed within the processing chamber or may be introduced via placement by a wafer handling robot, e.g., retrieved from a designated location, such as a particular wafer slot on a FOUP or from a special holding station located on the apparatus, by the wafer handling robot of a vacuum transfer module and then placed within the processing chamber. The controller of the apparatus may receive a command to perform a chamber cleaning operation which may cause the controller to cause the apparatus to perform the operations of the technique of FIG. 16.

The cleaning wafer may be the size and shape of atypical wafer subjected to processing within the processing chamber but may be specially configured so as to have a diffusively reflective upper surface. In other words, the surface of the cleaning wafer that faces towards the one or more light sources (or that is ultimately illuminated thereby) may have a somewhat rough surface that may act to diffusively reflect and scatter the radiation from the one or more light sources in a random, but relatively uniform, manner around the wafer. For example, the cleaning wafer may have a surface roughness on the side that faces the one or more light sources that is comparable to one to two wavelengths of the light emitted by the one or more light sources. In some implementations, the cleaning wafer may have an upper surface with a surface finish where the diffuse reflectance is between 60% and 100% of the total reflectance in the wavelength band(s) of interest, e.g., in the 400 nm to 490 nm range and/or the 600 nm to 1300 nm range.

In some implementations, the surface of the calibration wafer may be coated with the same or a similar material to what is present on the wafers that are dry developed within the processing chamber. For example, if the processing chamber is used to dry develop wafers having a metal-containing photoresist, e.g., a photoresist containing tin, hafnium, or tellurium then the cleaning wafer may have an upper surface that may be coated with a similar material, e.g., tin, hafnium, or tellurium. The underside of the cleaning wafer may, for example, be kept coating-free to ensure that the wafer support surface encounters only materials similar to those introduced to the processing chamber during actual wafer processing.

In block 1604, the cleaning wafer may be caused to be illuminated by the one or more light sources. Light from the one or more light sources that strikes the wafer may diffusively reflect off of the wafer and may then strike various surfaces of the processing chamber and equipment therein, e.g., portions of the gas distribution system, the pedestal, etc., that may, for example, have volatile halides present thereupon. When the reflected light strikes such surfaces, it may subject them to radiative heating, thereby assisted with driving out any resident volatile halides that may be resident thereupon.

In some implementations, the processing chamber may be maintained at a relatively low absolute pressure, e.g., a few tens of Torr, using a gas, such as Helium, having a relatively high thermal conductivity (e.g., ˜0.15 W/mK or higher at 300K) that may act to help equalize temperature differences that may exist in the temperature wall surfaces that it contacts, thus leading a more uniform chamber wall temperature distribution. In some such implementations, the exhaust system and gas distribution system of the processing chamber may be controlled during the cleaning operation to maintain a relatively high volumetric flow rate through the processing chamber, e.g., equivalent to, for example, at least 6× the free volume of the processing chamber per minute (1/10^{th} of the free volume of the processing chamber per second). Such gas flow may cause molecular drag effects that may act to help draw volatile halides, water, and, for example, organometallic halides and metallic halides, e.g., tin-alkyl-bromides, that may be released during the cleaning process out of the processing chamber.

In some implementations, the cleaning wafer may be supported above the wafer support surface of the pedestal within the processing chamber, e.g., using lift pins, during at least part of the exposure of the cleaning wafer to the light from the one or more light sources. Raising the cleaning wafer off of the wafer support surface in such a manner allows for potential process residues that may have collected on portions of the wafer support surface normally covered by the wafer to be able to potentially be removed, e.g., through heating provided by reflected radiation from the one or more light sources.

Once the cleaning operation has completed, e.g., after a predetermined period of time, the cleaning wafer may then be removed from the processing chamber in block 1606 and normal processing operations may resume.

It will be appreciated that any of the techniques discussed herein that involve radiatively heating a wafer to a temperature within a particular temperature range or to a particular temperature may be performed in a closed-loop manner with, for example, data from a remote temperature sensor. For example, the apparatuses discussed herein may be equipped with one or more remote temperature sensors, e.g., pyrometers, that may be used to obtain temperature measurements of the wafer without needing to be in contact with the wafer. For example, a pyrometer mounted within the processing chamber or mounted externally to the processing chamber but able to have line-of-sight to the wafer through a window of the processing chamber may be used to obtain temperature measurements of one or more points on the wafer. In some implementations, such measurements may be used to guide control of the one or more light sources, e.g., the controller of the apparatus may cause the intensity of the one or more light sources to be reduced or the one or more light sources to be turned off for a period of time and then be turned on again when the wafer temperature reaches a certain temperature threshold so as to cause the amount of radiative heating provided to the wafer to be reduced. Such reductions in intensity or illumination time reduce the amount of heat delivered to the wafer, preventing it from potentially exceeding the relevant temperature range for the heating operation in question. If necessary, the controller may also cause the one or more light sources to increase in intensity or reduce the period(s) of time in which the one or more light sources are turned off in order to cause the wafer temperature to rise again should the wafer temperature start to drift below the bottom end of the relevant temperature range. For example, it may be desirable to keep the wafer temperature below a level of about 200° C. to avoid damaging the wafer and/or the structures or features that may be included thereupon. The controller may be configured to monitor the wafer temperature and then adjust either the intensity of light emitted by the one or more light sources (e.g., by reducing the voltage or current supplied to LEDs or other lighting devices or by rapidly cycling LEDs between on and off states, e.g., similar to how consumer LED dimmable bulbs operate) or the duration of illumination of the one or more light sources so as to reduce the amount of radiative heating that is provided should the wafer temperature approach the 200° C. mark.

It will be understood that the techniques, methods, and processes discussed herein may be implemented in an apparatus such as the apparatuses discussed herein by way of one or more controllers, such as the controller 156 discussed above.

In some implementations, the controller may be part of a system, which may include or be part of the above-described examples. Such systems may include semiconductor processing equipment, including a processing tool or tools, chamber or chambers, a platform or platforms for processing, and/or specific processing components (a wafer pedestal, a gas flow system, etc.). These systems may be integrated with electronics for controlling their operation before, during, and after processing of a semiconductor wafer or substrate. The electronics may be referred to as the “controller,” which may control various components or subparts of the system or systems. The controller, depending on the processing requirements and/or the type of system, may be programmed to control any of the processes disclosed herein, including the delivery of processing gases, temperature settings (e.g., heating and/or cooling), light source control for radiative heating, pressure settings, vacuum settings, power settings, radio frequency (RF) generator settings, RF matching circuit settings, frequency settings, flow rate settings, fluid delivery settings, positional and operation settings, wafer transfers into and out of a tool or chamber and other transfer tools and/or load locks connected to or interfaced with a specific system.

Broadly speaking, the controller may be defined as electronics having various integrated circuits, logic, memory, and/or software that receive instructions, issue instructions, control operation, enable cleaning operations, enable endpoint measurements, and the like. The integrated circuits may include chips in the form of firmware that store program instructions, digital signal processors (DSPs), chips defined as application specific integrated circuits (ASICs), and/or one or more microprocessors, or microcontrollers that execute program instructions (e.g., software). Program instructions may be instructions communicated to the controller in the form of various individual settings (or program files), defining operational parameters for carrying out a particular process on or for a semiconductor wafer or to a system. The operational parameters may, in some embodiments, be part of a recipe defined by process engineers to accomplish one or more processing steps during the fabrication of one or more layers (such as dry development of a photopatterned photoresist layer), materials, metals, oxides, silicon, silicon oxide, surfaces, circuits, and/or dies of a wafer.

The controller, in some implementations, may be a part of or coupled to a computer that is integrated with, coupled to the system, otherwise networked to the system, or a combination thereof. For example, the controller may be in the “cloud” or all or a part of a fab host computer system, which can allow for remote access of the wafer processing. The computer may enable remote access to the system to monitor current progress of fabrication operations, examine a history of past fabrication operations, examine trends or performance metrics from a plurality of fabrication operations, to change parameters of current processing, to set processing steps to follow a current processing, or to start a new process. In some examples, a remote computer (e.g. a server) can provide process recipes to a system over a network, which may include a local network or the Internet. The remote computer may include a user interface that enables entry or programming of parameters and/or settings, which are then communicated to the system from the remote computer. In some examples, the controller receives instructions in the form of data, which specify parameters for each of the processing steps to be performed during one or more operations. It should be understood that the parameters may be specific to the type of process to be performed and the type of tool that the controller is configured to interface with or control. Thus, as described above, the controller may be distributed, such as by comprising one or more discrete controllers that are networked together and working towards a common purpose, such as the processes and controls described herein. An example of a distributed controller for such purposes would be one or more integrated circuits on a chamber in communication with one or more integrated circuits located remotely (such as at the platform level or as part of a remote computer) that combine to control a process on the chamber.

Without limitation, while the above discussion has focused on dry development chambers, further example systems may include a plasma etch chamber or module, a deposition chamber or module, a spin-rinse chamber or module, a metal plating chamber or module, a clean chamber or module, a bevel edge etch chamber or module, a physical vapor deposition (PVD) chamber or module, a chemical vapor deposition (CVD) chamber or module, an atomic layer deposition (ALD) chamber or module, an atomic layer etch (ALE) chamber or module, an ion implantation chamber or module, a track chamber or module, and any other semiconductor processing systems that may be associated or used in the fabrication and/or manufacturing of semiconductor wafers.

As noted above, depending on the process step or steps to be performed by the tool, the controller might communicate with one or more of other tool circuits or modules, other tool components, cluster tools, other tool interfaces, adjacent tools, neighboring tools, tools located throughout a factory, a main computer, another controller, or tools used in material transport that bring containers of wafers to and from tool locations and/or load ports in a semiconductor manufacturing factory.

The use, if any, of ordinal indicators, e.g., (a), (b), (c) . . . or the like, in this disclosure and claims is to be understood as not conveying any particular order or sequence, except to the extent that such an order or sequence is explicitly indicated. For example, if there are three steps labeled (i), (ii), and (iii), it is to be understood that these steps may be performed in any order (or even concurrently, if not otherwise contraindicated) unless indicated otherwise. For example, if step (ii) involves the handling of an element that is created in step (i), then step (ii) may be viewed as happening at some point after step (i). Similarly, if step (i) involves the handling of an element that is created in step (ii), the reverse is to be understood. It is also to be understood that use of the ordinal indicator “first” herein, e.g., “a first item,” should not be read as suggesting, implicitly or inherently, that there is necessarily a “second” instance, e.g., “a second item.”

It is to be understood that the phrases “for each <item> of the one or more <items>,” “each <item> of the one or more <items>,” or the like, if used herein, are inclusive of both a single-item group and multiple-item groups, i.e., the phrase “for . . . each” is used in the sense that it is used in programming languages to refer to each item of whatever population of items is referenced. For example, if the population of items referenced is a single item, then “each” would refer to only that single item (despite the fact that dictionary definitions of “each” frequently define the term to refer to “every one of two or more things”) and would not imply that there must be at least two of those items. Similarly, the term “set” or “subset” should not be viewed, in itself, as necessarily encompassing a plurality of items—it will be understood that a set or a subset can encompass only one member or multiple members (unless the context indicates otherwise).

Terms such as “about,” “approximately,” “substantially,” “nominal,” or the like, when used in reference to quantities or similar quantifiable properties, are to be understood to be inclusive of values within +10% of the values or relationship specified (as well as inclusive of the actual values or relationship specified), unless otherwise indicated.

The term “between,” as used herein and when used with a range of values, is to be understood, unless otherwise indicated, as being inclusive of the start and end values of that range. For example, between 1 and 5 is to be understood to be inclusive of the numbers 1, 2, 3, 4, and 5, not just the numbers 2, 3, and 4.

It is understood that the examples and embodiments described herein are for illustrative purposes only and that various modifications or changes in light thereof will be suggested to persons skilled in the art. Although various details have been omitted for clarity's sake, various design alternatives may be implemented. Therefore, the present examples are to be considered as illustrative and not restrictive, and the disclosure is not to be limited to the details given herein but may be modified within the scope of the disclosure.

It is to be understood that the above disclosure, while focusing on a particular example implementation or implementations, is not limited to only the discussed example, but may also apply to similar variants and mechanisms as well, and such similar variants and mechanisms are also considered to be within the scope of this disclosure. At the very least, the following numbered implementations are considered to be within the scope of this disclosure, although this is not considered an exclusive list of implementations that are within the scope of this disclosure.

Implementation 1: An apparatus including:
a processing chamber;
a pedestal located within the processing chamber and having a wafer support surface configured to support a wafer during dry development processing of the wafer within the processing chamber;
a pedestal cooling system configured to cool at least the wafer support surface of the pedestal;
one or more light sources positioned so as to direct light at a location within the processing chamber and on or above the pedestal; and
a gas distribution system with one or more inlets and a plurality of outlets, the gas distribution system configured to direct gas flowed therethrough out of the outlets into a region above the wafer support surface of the pedestal.

Implementation 2: The apparatus of implementation 1, wherein at least one of the one or more light sources is configured to emit light predominantly in the blue spectrum of wavelengths between 400 nm to 490 nm, light predominantly in the infrared spectrum of wavelengths between 800 nm to 1300 nm, or light predominantly in the blue and infrared spectrums of wavelengths between 400 nm to 490 nm and 800 nm to 1300 nm, respectively.

Implementation 3: The apparatus of implementation 1, wherein at least one of the one or more light sources is configured to emit light predominantly in the blue spectrum of wavelengths between 400 nm to 490 nm.

Implementation 4: The apparatus of implementation 1, wherein at least one of the one or more light sources is configured to emit light predominantly in the infrared spectrum of wavelengths between 800 nm to 1300 nm.

Implementation 5: The apparatus of implementation 1, wherein there are a plurality of light sources and at least a majority of the light sources are configured to emit light predominantly in the blue spectrum of wavelengths between 400 nm to 490 nm, light predominantly in the infrared spectrum of wavelengths between 800 nm to 1300 nm, or light predominantly in the blue and infrared spectrums of wavelengths between 400 nm to 490 nm and 800 nm to 1300 nm, respectively.

Implementation 6: The apparatus of implementation 1, wherein there are a plurality of light sources and at least a majority of the light sources are configured to emit light predominantly in the blue spectrum of wavelengths between 400 nm to 490 nm.

Implementation 7: The apparatus of implementation 1, wherein there are a plurality of light sources and at least a majority of the light sources are configured to emit light predominantly in the infrared spectrum of wavelengths between 800 nm to 1300 nm.

Implementation 8: The apparatus of implementation 1, wherein each of the one or more light sources is configured to emit light predominantly in the blue spectrum of wavelengths between 400 nm to 490 nm, light predominantly in the infrared spectrum of wavelengths between 800 nm to 1300 nm, or light predominantly in the blue and infrared spectrums of wavelengths between 400 nm to 490 nm and 800 nm to 1300 nm, respectively.

Implementation 9: The apparatus of implementation 1, wherein each of the one or more light sources is configured to emit light predominantly in the blue spectrum of wavelengths between 400 nm to 490 nm.

Implementation 10: The apparatus of implementation 1, wherein each of the one or more light sources is configured to emit light predominantly in the infrared spectrum of wavelengths between 800 nm to 1300 nm.

Implementation 11: The apparatus of implementation 1, wherein each of the one or more light sources is configured to emit light predominantly in the blue spectrum of wavelengths between 400 nm to 490 nm, light predominantly in the infrared spectrum of wavelengths between 800 nm to 1300 nm, or light predominantly in the blue and infrared spectrums of wavelengths between 400 nm to 490 nm and 800 nm to 1300 nm, respectively.

Implementation 12: The apparatus of implementation 2, wherein at least one of the one or more light sources is an incandescent infrared lamp, an infrared light emitting diode, or a blue light emitting diode.

Implementation 13: The apparatus of any one of implementations 1 through 12, wherein the one or more light sources include a plurality of light emitting diodes (LEDs) distributed throughout a circular or annular area.

Implementation 14: The apparatus of any one of implementations 1 through 13, further including one or more windows, each window interposed between one of the one or more light sources and the wafer support surface, wherein the one or more windows each have a region that is optically transmissive to light at least having a wavelength or wavelengths in a range or ranges between 400 nm to 490 nm, between 800 nm to 1300 nm, or between 400 nm to 490 nm and between 800 nm to 1300 nm.

Implementation 15: The apparatus of implementation 14, wherein the one or more windows comprise aluminum oxide or silicon oxide.

Implementation 16: The apparatus of any one of implementations 1 through 15, wherein:
the gas distribution system includes a showerhead that extends over, and is vertically offset from, the wafer support surface, and
at least some of the outlets are distributed across, and extend through, a first portion of a faceplate of the showerhead having a first surface that faces towards the wafer support surface.

Implementation 17: The apparatus of implementation 16, wherein:
the one or more light sources include a plurality of light-emitting diodes (LEDs), and
the LEDs in the plurality of LEDs are distributed across a second portion of the faceplate.

Implementation 18: The apparatus of implementation 17, wherein the LEDs in the plurality of LEDs are interspersed between the outlets located within the second portion of the faceplate.

Implementation 19: The apparatus of either implementation 17 or implementation 18, wherein the first portion and the second portion are both circular, annular, or radially symmetric in shape and are centered on one another.

Implementation 20: The apparatus of implementation 16, wherein:
the showerhead is interposed between the wafer support surface and at least some of the one or more light sources, and
the showerhead has a region that is at least partially optically transmissive to light having a wavelength or wavelengths in a range or ranges between 400 nm to 490 nm, between 800 nm to 1300 nm, or between 400 nm to 490 nm and between 800 nm to 1300 nm.

Implementation 21: The apparatus of implementation 16, wherein:
the showerhead includes a faceplate having the outlets distributed thereacross, and
at least the faceplate of the showerhead is made of a material including silicon oxide or aluminum oxide.

Implementation 22: The apparatus of any one of implementations 1 through 13, further including one or more windows, each window interposed between one of the one or more light sources and the wafer support surface, or implementations 14 through 21, wherein:
the one or more windows seal a corresponding one or more apertures of the processing chamber, and
the one or more light sources are located outside of the processing chamber and are positioned to emit light through the one or more windows and into the processing chamber.

Implementation 23: The apparatus of any one of implementations 1 through 13, further including one or more windows, each window interposed between one of the one or more light sources and the wafer support surface, or implementations 14 through 21, wherein the one or more light sources are light emitting diodes located within the processing chamber and at least some of the one or more windows are located within the processing chamber as well.

Implementation 24: The apparatus of any one of implementations 1 through 23, further including a controller configured to:
a) determine that a wafer within the processing chamber is to be prepared for a dry development process,
b) cause the pedestal cooling system to cool the wafer to a temperature in a first temperature range while the wafer is supported by the wafer support surface,
c) cause the gas distribution system to flow a first set of one or more processing gases through the plurality of outlets and across the wafer while the temperature of the wafer is in the first temperature range to perform the dry development process, and
d) cause the one or more light sources to illuminate the wafer after (c) to heat the wafer to a temperature in a second temperature range with a lower limit higher than an upper limit of the first temperature range.

Implementation 25: The apparatus of implementation 24, further including a pyrometer configured to obtain temperature measurements of the wafer at least during (d), wherein the controller is further configured to:
monitor the temperature of the wafer using the pyrometer, and
adjust an intensity level of the one or more light sources based on the temperature of the wafer so as to keep the temperature of the wafer below 200° C.

Implementation 26: The apparatus of implementation 24, wherein the controller is further configured to:
(e) cause an inert gas to flow through the gas distribution system and the outlets thereof after (c), and
perform (d) after or during (e).

Implementation 27: The apparatus of implementation 24, wherein the inert gas includes argon, nitrogen, xenon, helium, krypton, or combinations of any two or more thereof.

Implementation 28: The apparatus of either implementation 26 or 27, further including an exhaust system connected with the processing chamber, wherein the controller is further configured to:
cause the exhaust system to evacuate gas from the processing chamber during at least part of (e), and
perform (d) after a residual molar density of the first set of one or more process gases within the processing chamber is reduced to 10% or less of the molar density of the first set of one or more processes gases within the processing chamber during steady-state gas flow occurring during (c).

Implementation 29: The apparatus of any one of implementations 24 through 28, wherein the controller is configured to cause the one or more light sources to illuminate the wafer prior to (b) to heat the wafer to a temperature within a third temperature range.

Implementation 30: The apparatus of any one of implementations 24 through 28, further including a lift pin mechanism having a plurality of lift pins, wherein:
the lift pin mechanism is configured such that the lift pins are controllably movable between a first position and a second position relative to the pedestal,
each lift pin, in the first position, does not extend upward past the wafer support surface,
each lift pin, in the second position, extends upward past the wafer support surface, and
wherein the controller is configured to cause the lift pins of the lift pin mechanism to be in the first position during at least part of both (b) and (c).

Implementation 31: The apparatus of implementation 30, wherein the controller is configured to cause the lift pins of the lift pin mechanism to be in the second position during at least part of (d).

Implementation 32: The apparatus of either implementation 30 or implementation 31, wherein the controller is configured to:
cause the one or more light sources to illuminate the wafer prior to (b) to heat the wafer to a temperature within a third temperature range, and
cause the lift pins of the lift pin mechanism to be in the second position during at least part of the illumination of the wafer prior to (b).

Implementation 33: The apparatus of any one of implementations 24 through 32, wherein the controller is configured to:
receive a command to perform a chamber cleaning operation;
cause a cleaning wafer to be placed within the first chamber, wherein the cleaning wafer has a reflective, high-diffusivity finish on a surface thereof;
cause the one or more light sources to illuminate the surface of the cleaning wafer with the reflective, high-diffusivity finish for a first period of time; and
remove the cleaning wafer from the first chamber after the first period of time.

Implementation 34: The apparatus of implementation 33, wherein the reflective, high-diffusivity coating is made of tin, tellurium, or hafnium.

Implementation 35: The apparatus of either implementation 33 or implementation 34, wherein the surface with the reflective, high-diffusivity finish has a surface roughness with a magnitude equivalent to one to two wavelengths of the light from the one or more light sources that illuminates the wafer.

Implementation 36: The apparatus of any one of implementations 33 through 35, further including the cleaning wafer.

Implementation 37: An apparatus including:
a first chamber;
a second chamber;
a passage configured to connect the first chamber and the second chamber, the passage sized to permit a wafer to be moved therethrough and along a first path between the first chamber and the second chamber;
a pedestal located within the first chamber and having a wafer support surface configured to support a wafer during dry development processing of the wafer within the first chamber;
a pedestal cooling system configured to cool at least the wafer support surface of the pedestal;
a gas distribution system with one or more inlets and a plurality of outlets, the gas distribution system configured to direct gas flowed therethrough out of the outlets into a region above the wafer support surface of the pedestal; and
one or more light sources positioned in at least one of: within the first chamber and adjacent to the passage, within the passage, or within the second chamber, wherein the one or more light sources are configured to direct light at a location through which a wafer will transit when being moved from the first chamber and through the second chamber.

Implementation 38: The apparatus of implementation 37, wherein:
the passage includes a valve mechanism configured to seal the passage when in a first configuration, and
the one or more light sources are proximate a side of the valve mechanism closest to the pedestal.

Implementation 39: The apparatus of implementation 37, wherein:
the passage includes a valve mechanism configured to seal the passage when in a first configuration, and
the one or more light sources are proximate a side of the valve mechanism furthest from the pedestal.

Implementation 40: The apparatus of implementation 37, wherein:
the passage includes a valve mechanism configured to seal the passage when in a first configuration,
the one or more light sources is a plurality of light sources, and
the one or more light sources includes a first set of one or more of the light sources that are positioned such that the valve mechanism is interposed between the first set of light sources and the pedestal and a second set of one or more of the light sources that are positioned so as to be horizontally interposed between the valve mechanism and the pedestal.

Implementation 41: The apparatus of any one of implementations 38 through 40, wherein the one or more light sources are configured to generate at least an elongate illumination area of at least width D in a direction perpendicular to the first path and in a first reference plane when powered, wherein D is a diameter of the wafer.

Implementation 42: The apparatus of any one of implementations 38 through 41, wherein the second chamber is a vacuum transfer module having one or more wafer handling robots.

Implementation 43: The apparatus of implementation 42, further including a controller configured to:
a) determine that a wafer within the first chamber is to be prepared for a dry development process,
b) cause the pedestal cooling system to cool the wafer to a temperature in a first temperature range while the wafer is supported by the wafer support surface,
c) cause the gas distribution system to flow a first set of one or more processing gases through the plurality of outlets and across the wafer while the temperature of the wafer is in the first temperature range to perform the dry development process,
d) cause the wafer to be removed from the wafer support surface, out of the first chamber, through the passage, and through the second chamber, and
e) cause the one or more light sources to illuminate the wafer after the wafer has been removed from the wafer support surface and while the wafer is being moved out of the first chamber in order to heat the wafer to a temperature in a second temperature range with a lower limit higher than an upper limit of the first temperature range.

Implementation 44: The apparatus of implementation 43, further including an exhaust system configured to evacuate gas from the first chamber when powered, wherein the controller is configured to cause the exhaust system to activate to maintain a lower pressure within the first chamber than within the second chamber during at least part of (d) and (e).

Implementation 45: The apparatus of either implementation 43 or implementation 44, wherein the controller is configured to cause the one or more light sources to illuminate the wafer while the wafer is moved into the first chamber from the second chamber prior to (a) in order to heat the wafer to a temperature in a third temperature range with a lower limit higher than an upper limit of the first temperature range.

Implementation 46: The apparatus of either implementation 43, further including an exhaust system configured to evacuate gas from the first chamber when powered, or implementation 44, wherein the controller is configured to:
f) cause the one or more light sources to illuminate the wafer while the wafer is moved into the first chamber from the second chamber prior to (a) in order to heat the wafer to a temperature in a third temperature range with a lower limit higher than an upper limit of the first temperature range, and
g) cause the exhaust system to activate to maintain a lower pressure within the first chamber than within the second chamber during at least part of (f).

Implementation 47: The apparatus of implementation 37, wherein:
the second chamber has an internal volume that is larger than a cylindrical reference volume of diameter D, wherein D is a diameter of the wafer, and
the one or more light sources are arranged so as to illuminate a circular region of diameter D within the second chamber and in a first reference plane.

Implementation 48: The apparatus of implementation 47, further including a transfer module including one or more wafer handling robots, wherein the second chamber is interposed between the first chamber and the transfer module.

Implementation 49: The apparatus of either implementation 47 or 48, further including a controller configured to:
a) determine that a wafer within the first chamber is to be prepared for a dry development process,
b) cause the pedestal cooling system to cool the wafer to a temperature in a first temperature range while the wafer is supported by the wafer support surface,
c) cause the gas distribution system to flow a first set of one or more processing gases through the plurality of outlets and across the wafer while the temperature of the wafer is in the first temperature range to perform the dry development process,
d) cause the wafer to be removed from the wafer support surface, out of the first chamber, through the passage, and into the second chamber, and
e) cause the one or more light sources to illuminate the wafer after the wafer has been moved from the first chamber to the second chamber in order to heat the wafer to a temperature in a second temperature range with a lower limit higher than an upper limit of the first temperature range.

Implementation 50: The apparatus of implementation 49, wherein the controller is configured to cause the one or more light sources to illuminate the wafer while the wafer is resident in the second chamber prior to being moved into the first chamber and prior to (a) in order to heat the wafer to a temperature in a third temperature range with a lower limit higher than an upper limit of the first temperature range.

Implementation 51: The apparatus of any one of implementations 37 through 50, wherein at least one of the one or more light sources is configured to emit light predominantly in the blue spectrum of wavelengths between 400 nm to 490 nm, light predominantly in the infrared spectrum of wavelengths between 800 nm to 1300 nm, or light predominantly in the blue and infrared spectrums of wavelengths between 400 nm to 490 nm and 800 nm to 1300 nm, respectively.

Implementation 52: The apparatus of any one of implementations 37 through 50, wherein at least one of the one or more light sources is configured to emit light predominantly in the blue spectrum of wavelengths between 400 nm to 490 nm.

Implementation 53: The apparatus of any one of implementations 37 through 50, wherein at least one of the one or more light sources is configured to emit light predominantly in the infrared spectrum of wavelengths between 800 nm to 1300 nm.

Implementation 54: The apparatus of any one of implementations 37 through 50, wherein there are a plurality of light sources and at least a majority of the light sources are configured to emit light predominantly in the blue spectrum of wavelengths between 400 nm to 490 nm, light predominantly in the infrared spectrum of wavelengths between 800 nm to 1300 nm, or light predominantly in the blue and infrared spectrums of wavelengths between 400 nm to 490 nm and 800 nm to 1300 nm, respectively.

Implementation 55: The apparatus of any one of implementations 37 through 50, wherein there are a plurality of light sources and at least a majority of the light sources are configured to emit light predominantly in the blue spectrum of wavelengths between 400 nm to 490 nm.

Implementation 56: The apparatus of any one of implementations 37 through 50, wherein there are a plurality of light sources and at least a majority of the light sources are configured to emit light predominantly in the infrared spectrum of wavelengths between 800 nm to 1300 nm.

Implementation 57: The apparatus of any one of implementations 37 through 50, wherein each of the one or more light sources is configured to emit light predominantly in the blue spectrum of wavelengths between 400 nm to 490 nm, light predominantly in the infrared spectrum of wavelengths between 800 nm to 1300 nm, or light predominantly in the blue and infrared spectrums of wavelengths between 400 nm to 490 nm and 800 nm to 1300 nm, respectively.

Implementation 58: The apparatus of any one of implementations 37 through 50, wherein each of the one or more light sources is configured to emit light predominantly in the blue spectrum of wavelengths between 400 nm to 490 nm.

Implementation 59: The apparatus of any one of implementations 37 through 50, wherein each of the one or more light sources is configured to emit light predominantly in the infrared spectrum of wavelengths between 800 nm to 1300 nm.

Implementation 60: The apparatus of any one of implementations 37 through 50, wherein each of the one or more light sources is configured to emit light predominantly in the blue spectrum of wavelengths between 400 nm to 490 nm, light predominantly in the infrared spectrum of wavelengths between 800 nm to 1300 nm, or light predominantly in the blue and infrared spectrums of wavelengths between 400 nm to 490 nm and 800 nm to 1300 nm, respectively.

Implementation 61: The apparatus of any one of implementations 51 through 60, wherein each light source of the one or more light sources is an incandescent infrared lamp, an infrared light emitting diode, or a blue light emitting diode.

Implementation 62: A method including:
a) placing a wafer on a wafer support surface of a pedestal in a processing chamber;
b) cooling the wafer to a temperature in a first temperature range while the wafer is supported by the wafer support surface;
c) flowing a first set of one or more processing gases through a plurality of outlets of a gas distribution system and across the wafer while the temperature of the wafer is in the first temperature range to perform a dry development process; and
d) illuminating the wafer with one or more light sources after (c) and within the processing chamber to heat the wafer to a temperature in a second temperature range with a lower limit higher than an upper limit of the first temperature range.

Implementation 63: The method of implementation 62, wherein at least one of the one or more light sources is configured to emit light predominantly in the blue spectrum of wavelengths between 400 nm to 490 nm, light predominantly in the infrared spectrum of wavelengths between 800 nm to 1300 nm, or light predominantly in the blue and infrared spectrums of wavelengths between 400 nm to 490 nm and 800 nm to 1300 nm, respectively.

Implementation 64: The method of implementation 62, wherein at least one of the one or more light sources is configured to emit light predominantly in the blue spectrum of wavelengths between 400 nm to 490 nm.

Implementation 65: The method of implementation 62, wherein at least one of the one or more light sources is configured to emit light predominantly in the infrared spectrum of wavelengths between 800 nm to 1300 nm.

Implementation 66: The method of implementation 62, wherein there are a plurality of light sources and at least a majority of the light sources are configured to emit light predominantly in the blue spectrum of wavelengths between 400 nm to 490 nm, light predominantly in the infrared spectrum of wavelengths between 800 nm to 1300 nm, or light predominantly in the blue and infrared spectrums of wavelengths between 400 nm to 490 nm and 800 nm to 1300 nm, respectively.

Implementation 67: The method of implementation 62, wherein there are a plurality of light sources and at least a majority of the light sources are configured to emit light predominantly in the blue spectrum of wavelengths between 400 nm to 490 nm.

Implementation 68: The method of implementation 62, wherein there are a plurality of light sources and at least a majority of the light sources are configured to emit light predominantly in the infrared spectrum of wavelengths between 800 nm to 1300 nm.

Implementation 69: The method of implementation 62, wherein each of the one or more light sources is configured to emit light predominantly in the blue spectrum of wavelengths between 400 nm to 490 nm, light predominantly in the infrared spectrum of wavelengths between 800 nm to 1300 nm, or light predominantly in the blue and infrared spectrums of wavelengths between 400 nm to 490 nm and 800 nm to 1300 nm, respectively.

Implementation 70: The method of implementation 62, wherein each of the one or more light sources is configured to emit light predominantly in the blue spectrum of wavelengths between 400 nm to 490 nm.

Implementation 71: The method of implementation 62, wherein each of the one or more light sources is configured to emit light predominantly in the infrared spectrum of wavelengths between 800 nm to 1300 nm.

Implementation 72: The method of implementation 62, wherein each of the one or more light sources is configured to emit light predominantly in the blue spectrum of wavelengths between 400 nm to 490 nm, light predominantly in the infrared spectrum of wavelengths between 800 nm to 1300 nm, or light predominantly in the blue and infrared spectrums of wavelengths between 400 nm to 490 nm and 800 nm to 1300 nm, respectively.

Implementation 73: The method of implementation 62 through 73, wherein each light source of the one or more light sources is an incandescent infrared lamp, an infrared light emitting diode, or a blue light emitting diode.

Implementation 74: The method of any one of implementations 62 through 73, wherein the one or more light sources include a plurality of light emitting diodes (LEDs) distributed throughout a circular or annular area.

Implementation 75: The method of any one of implementations 62 through 74, further including directing the light from the one or more light sources through one or more windows, each window interposed between one of the one or more light sources and the wafer support surface, wherein the one or more windows each have a region that is optically transmissive to light at least having a wavelength or wavelengths in a range of between 400 nm to 490 nm, between 800 nm to 1300 nm, or between 400 nm to 490 nm and 800 nm to 1300 nm.

Implementation 76: The method of implementation 75, wherein the one or more windows are made from a material including aluminum oxide or silicon oxide.

Implementation 77: The method of any one of implementations 62 through 76, wherein:
the gas distribution system includes a showerhead that extends over, and is vertically offset from, the wafer support surface, and
at least some of the outlets are distributed across, and extend through, a first portion of a faceplate of the showerhead having a first surface that faces towards the wafer support surface.

Implementation 78: The method of implementation 77, wherein:
the one or more light sources include a plurality of light-emitting diodes (LEDs), and
the LEDs in the plurality of LEDs are distributed across a second portion of the faceplate.

Implementation 79: The method of implementation 78, wherein the LEDs in the plurality of LEDs are interspersed between the outlets located within the second portion of the faceplate.

Implementation 80: The method of either implementation 78 or implementation 79, wherein the first portion and the second portion are both circular, annular, or radially symmetric in shape and are centered on one another.

Implementation 81: The method of implementation 77, wherein:
the showerhead is interposed between the wafer support surface and at least some of the one or more light sources, and
the showerhead has a region that is at least partially optically transmissive to light having a wavelength or wavelengths in a range or ranges between 400 nm to 490 nm, between 800 nm to 1300 nm, or between 400 nm to 490 nm and between 800 nm to 1300 nm.

Implementation 82: The method of implementation 77, wherein:
the showerhead includes a faceplate having the outlets distributed thereacross, and
at least the faceplate of the showerhead is made of a material including silicon oxide or aluminum oxide.

Implementation 83: The method of any one of implementations 62 through 74, further including emitting the light from the one or more light sources through one or more windows, each window interposed between one of the one or more light sources and the wafer support surface, or implementations 75 through 82, wherein:
the one or more windows seal a corresponding one or more apertures of the processing chamber, and
the one or more light sources are located outside of the processing chamber and are positioned to emit light through the one or more windows and into the processing chamber.

Implementation 84: The method of any one of implementations 62 through 74, further including emitting the light from the one or more light sources through one or more windows, each window interposed between one of the one or more light sources and the wafer support surface, or implementations 75 through 82, wherein the one or more light sources are light emitting diodes located within the processing chamber and at least some of the one or more windows are located within the processing chamber as well.

Implementation 85: The method of implementation 62 through 84, further including:
monitoring the temperature of the wafer using a pyrometer, and
adjusting an intensity level of the one or more light sources based on the temperature of the wafer so as to keep the temperature of the wafer below 200° C.

Implementation 86: The method of implementation 62 through 84, further including:
(e) causing an inert gas to flow through the gas distribution system and the outlets thereof after (c), and performing (d) after or during (e).

Implementation 87: The method of implementation 62 through 84, wherein the inert gas includes argon, nitrogen, xenon, helium, krypton, or combinations of any two or more thereof.

Implementation 88: The method of either implementation 86 or 87, further including:
causing an exhaust system to evacuate gas from the processing chamber during at least part of (e), and
performing (d) after a residual molar density of the first set of one or more process gases within the processing chamber is reduced to 10% or less of the molar density of the first set of one or more processes gases within the processing chamber during steady-state gas flow occurring during (c).

Implementation 89: The method of any one of implementations 85 through 88, further including illuminating the wafer prior to (b) to heat the wafer to a temperature within a third temperature range.

Implementation 90: The method of any one of implementations 85 through 88, further including causing lift pins of a lift pin mechanism to be in a first position during at least part of both (b) and (c), wherein the lift pins are controllably movable between the first position and a second position relative to the pedestal, each lift pin, in the first position, does not extend upward past the wafer support surface, and each lift pin, in the second position, extends upward past the wafer support surface.

Implementation 91: The method of implementation 90, further including causing the lift pins of the lift pin mechanism to be in the second position during at least part of (d).

Implementation 92: The method of either implementation 90 or implementation 91, further including:
causing the one or more light sources to illuminate the wafer prior to (b) to heat the wafer to a temperature within a third temperature range, and
causing the lift pins of the lift pin mechanism to be in the second position during at least part of the illumination of the wafer prior to (b).

Implementation 93: The method of any one of implementations 85 through 92, further including:
receiving a command to perform a chamber cleaning operation;
causing a cleaning wafer to be placed within the first chamber, wherein the cleaning wafer has a reflective, high-diffusivity coating;
causing the one or more light sources to illuminate the cleaning wafer for a first period of time; and
removing the cleaning wafer from the first chamber after the first period of time.

Implementation 94: The method of implementation 93, wherein the reflective, high-diffusivity coating is made of tin, hafnium, or tellurium.

Implementation 95: The apparatus of either implementation 93 or implementation 94, wherein the surface with the reflective, high-diffusivity finish has a surface roughness with a magnitude equivalent to one to two wavelengths of the light from the one or more light sources used to illuminate the wafer.

Implementation 96: A method including:
a) placing a wafer on a wafer support surface of a pedestal in a processing chamber;
b) cooling the wafer to a temperature in a first temperature range while the wafer is supported by the wafer support surface;
c) flowing a first set of one or more processing gases through a plurality of outlets of a gas distribution system and across the wafer while the temperature of the wafer is in the first temperature range to perform a dry development process;
d) moving the wafer from the first chamber via a passage to a second chamber connected to the first chamber by the passage; and
e) illuminating the wafer with one or more light sources after (c) and while the wafer is either transiting the passage or within the second chamber in order to heat the wafer to a temperature in a second temperature range with a lower limit higher than an upper limit of the first temperature range.

Implementation 97: The method of implementation 96, wherein:
the passage includes a valve mechanism configured to seal the passage when in a first configuration, and
the one or more light sources are proximate a side of the valve mechanism closest to the pedestal.

Implementation 98: The method of implementation 96, wherein:
the passage includes a valve mechanism configured to seal the passage when in a first configuration, and
the one or more light sources are proximate a side of the valve mechanism furthest from the pedestal.

Implementation 99: The method of implementation 96, wherein:
the passage includes a valve mechanism configured to seal the passage when in a first configuration,
the one or more light sources is a plurality of light sources, and
the one or more light sources includes a first set of one or more of the light sources that are positioned such that the valve mechanism is interposed between the first set of light sources and the pedestal and a second set of one or more of the light sources that are positioned so as to be horizontally interposed between the valve mechanism and the pedestal.

Implementation 100: The method of any one of implementations 97 through 99, wherein:
the one or more light sources are configured to generate an elongate illumination area of at least width D in a direction perpendicular to the first path and in a first reference plane when powered, wherein D is a diameter of the wafer.

Implementation 101: The method of any one of implementations 97 through 100, wherein the second chamber is a transfer module having one or more wafer handling robots.

Implementation 102: The method of implementation 101, further including causing an exhaust system to activate to maintain a lower pressure within the first chamber than within the second chamber during at least part of (d) and (e).

Implementation 103: The method of either implementation 101 or implementation 102, further including causing the one or more light sources to illuminate the wafer while the wafer is moved into the first chamber from the second chamber prior to (a) in order to heat the wafer to a temperature in a third temperature range with a lower limit higher than an upper limit of the first temperature range.

Implementation 104: The method of implementation 102, further including:
f) causing the one or more light sources to illuminate the wafer while the wafer is moved into the first chamber from the second chamber prior to (a) in order to heat the wafer to a temperature in a third temperature range with a lower limit higher than an upper limit of the first temperature range, and
g) causing an exhaust system or the exhaust system to activate to maintain a lower pressure within the first chamber than within the second chamber during at least part of (f).

Implementation 105: The method of implementation 96, wherein:
the second chamber has an internal volume that is larger than a cylindrical reference volume of diameter D, wherein D is a diameter of the wafer, and
the one or more light sources are arranged so as to illuminate a circular region of diameter D within the second chamber and in a first reference plane.

Implementation 106: The method of implementation 105, further including a transfer module including one or more wafer handling robots, wherein the second chamber is interposed between the first chamber and the transfer module.

Implementation 107: The method of either of implementations 105 or 106, further including causing the one or more light sources to illuminate the wafer while the wafer is resident in the second chamber prior to being moved into the first chamber and prior to (a) in order to heat the wafer to a temperature in a third temperature range with a lower limit higher than an upper limit of the first temperature range.

Implementation 108: The method of implementation 96, wherein at least one of the one or more light sources is configured to emit light predominantly in the blue spectrum of wavelengths between 400 nm to 490 nm, light predominantly in the infrared spectrum of wavelengths between 800 nm to 1300 nm, or light predominantly in the blue and infrared spectrums of wavelengths between 400 nm to 490 nm and 800 nm to 1300 nm, respectively.

Implementation 109: The method of implementation 96, wherein at least one of the one or more light sources is configured to emit light predominantly in the blue spectrum of wavelengths between 400 nm to 490 nm.

Implementation 110: The method of implementation 96, wherein at least one of the one or more light sources is configured to emit light predominantly in the infrared spectrum of wavelengths between 800 nm to 1300 nm.

Implementation 111: The method of implementation 96, wherein there are a plurality of light sources and at least a majority of the light sources are configured to emit light predominantly in the blue spectrum of wavelengths between 400 nm to 490 nm, light predominantly in the infrared spectrum of wavelengths between 800 nm to 1300 nm, or light predominantly in the blue and infrared spectrums of wavelengths between 400 nm to 490 nm and 800 nm to 1300 nm, respectively.

Implementation 112: The method of implementation 96, wherein there are a plurality of light sources and at least a majority of the light sources are configured to emit light predominantly in the blue spectrum of wavelengths between 400 nm to 490 nm.

Implementation 113: The method of implementation 96, wherein there are a plurality of light sources and at least a majority of the light sources are configured to emit light predominantly in the infrared spectrum of wavelengths between 800 nm to 1300 nm.

Implementation 114: The method of implementation 96, wherein each of the one or more light sources is configured to emit light predominantly in the blue spectrum of wavelengths between 400 nm to 490 nm, light predominantly in the infrared spectrum of wavelengths between 800 nm to 1300 nm, or light predominantly in the blue and infrared spectrums of wavelengths between 400 nm to 490 nm and 800 nm to 1300 nm, respectively.

Implementation 115: The method of implementation 96, wherein each of the one or more light sources is configured to emit light predominantly in the blue spectrum of wavelengths between 400 nm to 490 nm.

Implementation 116: The method of implementation 96, wherein each of the one or more light sources is configured to emit light predominantly in the infrared spectrum of wavelengths between 800 nm to 1300 nm.

Implementation 117: The method of implementation 96, wherein each of the one or more light sources is configured to emit light predominantly in the blue spectrum of wavelengths between 400 nm to 490 nm, light predominantly in the infrared spectrum of wavelengths between 800 nm to 1300 nm, or light predominantly in the blue and infrared spectrums of wavelengths between 400 nm to 490 nm and 800 nm to 1300 nm, respectively.

Implementation 118: The method of any one of implementations 108 through 117, wherein each light source of the one or more light sources is an incandescent infrared lamp, an infrared light emitting diode, or a blue light emitting diode.

1. An apparatus comprising:
a processing chamber;
a pedestal located within the processing chamber and having a wafer support surface configured to support a wafer during dry development processing of the wafer within the processing chamber;
a pedestal cooling system configured to cool at least the wafer support surface of the pedestal;
one or more light sources positioned so as to direct light at a location within the processing chamber and on or above the pedestal; and
a gas distribution system with one or more inlets and a plurality of outlets, the gas distribution system configured to direct gas flowed therethrough out of the outlets into a region above the wafer support surface of the pedestal.

2. The apparatus of claim 1, wherein at least one of the one or more light sources is configured to emit light predominantly in the blue spectrum of wavelengths between 400 nm to 490 nm, light predominantly in the infrared spectrum of wavelengths between 800 nm to 1300 nm, or light predominantly in the blue and infrared spectrums of wavelengths between 400 nm to 490 nm and 800 nm to 1300 nm, respectively.

3. The apparatus of claim 1, wherein at least one of the one or more light sources is configured to emit light predominantly in the blue spectrum of wavelengths between 400 nm to 490 nm.

4. The apparatus of claim 1, wherein at least one of the one or more light sources is configured to emit light predominantly in the infrared spectrum of wavelengths between 800 nm to 1300 nm.

5. The apparatus of claim 1, wherein there are a plurality of light sources and at least a majority of the light sources are configured to emit light predominantly in the blue spectrum of wavelengths between 400 nm to 490 nm, light predominantly in the infrared spectrum of wavelengths between 800 nm to 1300 nm, or light predominantly in the blue and infrared spectrums of wavelengths between 400 nm to 490 nm and 800 nm to 1300 nm, respectively.

6. The apparatus of claim 1, wherein there are a plurality of light sources and at least a majority of the light sources are configured to emit light predominantly in the blue spectrum of wavelengths between 400 nm to 490 nm.

7. The apparatus of claim 1, wherein there are a plurality of light sources and at least a majority of the light sources are configured to emit light predominantly in the infrared spectrum of wavelengths between 800 nm to 1300 nm.

8. The apparatus of claim 1, wherein each of the one or more light sources is configured to emit light predominantly in the blue spectrum of wavelengths between 400 nm to 490 nm, light predominantly in the infrared spectrum of wavelengths between 800 nm to 1300 nm, or light predominantly in the blue and infrared spectrums of wavelengths between 400 nm to 490 nm and 800 nm to 1300 nm, respectively.

9. The apparatus of claim 1, wherein each of the one or more light sources is configured to emit light predominantly in the blue spectrum of wavelengths between 400 nm to 490 nm.

10. The apparatus of claim 1, wherein each of the one or more light sources is configured to emit light predominantly in the infrared spectrum of wavelengths between 800 nm to 1300 nm.

11. The apparatus of claim 1, wherein each of the one or more light sources is configured to emit light predominantly in the blue spectrum of wavelengths between 400 nm to 490 nm, light predominantly in the infrared spectrum of wavelengths between 800 nm to 1300 nm, or light predominantly in the blue and infrared spectrums of wavelengths between 400 nm to 490 nm and 800 nm to 1300 nm, respectively.

12. The apparatus of claim 1, wherein at least one of the one or more light sources is an incandescent infrared lamp, an infrared light emitting diode, or a blue light emitting diode.

13. The apparatus of claim 1, wherein the one or more light sources include a plurality of light emitting diodes (LEDs) distributed throughout a circular or annular area.

14. The apparatus of claim 1, further comprising one or more windows, each window interposed between one of the one or more light sources and the wafer support surface, wherein:
the one or more windows each have a region that is optically transmissive to light at least having a wavelength or wavelengths in a range or ranges between 400 nm to 490 nm, between 800 nm to 1300 nm, or between 400 nm to 490 nm and between 800 nm to 1300 nm.

15. The apparatus of claim 14, wherein the one or more windows comprise aluminum oxide or silicon oxide.

16. The apparatus of claim 1, wherein:
the gas distribution system includes a showerhead that extends over, and is vertically offset from, the wafer support surface, and
at least some of the outlets are distributed across, and extend through, a first portion of a faceplate of the showerhead having a first surface that faces towards the wafer support surface.

17. The apparatus of claim 16, wherein:
the one or more light sources include a plurality of light-emitting diodes (LEDs), and
the LEDs in the plurality of LEDs are distributed across a second portion of the faceplate.

18. The apparatus of claim 17, wherein the LEDs in the plurality of LEDs are interspersed between the outlets located within the second portion of the faceplate.

19. The apparatus of claim 17, wherein the first portion and the second portion are both circular, annular, or radially symmetric in shape and are centered on one another.

20. The apparatus of claim 16, wherein:
the showerhead is interposed between the wafer support surface and at least some of the one or more light sources, and
the showerhead has a region that is at least partially optically transmissive to light having a wavelength or wavelengths in a range or ranges between 400 nm to 490 nm, between 800 nm to 1300 nm, or between 400 nm to 490 nm and between 800 nm to 1300 nm.

21. The apparatus of claim 16, wherein:
the showerhead includes a faceplate having the outlets distributed thereacross, and
at least the faceplate of the showerhead is made of a material comprising silicon oxide or aluminum oxide.

22. The apparatus of claim 1, further comprising one or more windows, each window interposed between one of the one or more light sources and the wafer support surface, wherein:
the one or more windows seal a corresponding one or more apertures of the processing chamber, and
the one or more light sources are located outside of the processing chamber and are positioned to emit light through the one or more windows and into the processing chamber.

23. The apparatus of claim 1, further comprising one or more windows, each window interposed between one of the one or more light sources and the wafer support surface, wherein the one or more light sources are light emitting diodes located within the processing chamber and at least some of the one or more windows are located within the processing chamber as well.

24. The apparatus of claim 1, further comprising a controller configured to:
a) determine that a wafer within the processing chamber is to be prepared for a dry development process,
b) cause the pedestal cooling system to cool the wafer to a temperature in a first temperature range while the wafer is supported by the wafer support surface,
c) cause the gas distribution system to flow a first set of one or more processing gases through the plurality of outlets and across the wafer while the temperature of the wafer is in the first temperature range to perform the dry development process, and
d) cause the one or more light sources to illuminate the wafer after (c) to heat the wafer to a temperature in a second temperature range with a lower limit higher than an upper limit of the first temperature range.

25. The apparatus of claim 24, further comprising a pyrometer configured to obtain temperature measurements of the wafer at least during (d), wherein the controller is further configured to:
monitor the temperature of the wafer using the pyrometer, and
adjust an intensity level of the one or more light sources based on the temperature of the wafer so as to keep the temperature of the wafer below 200° C.

26. The apparatus of claim 24, wherein the controller is further configured to:
(e) cause an inert gas to flow through the gas distribution system and the outlets thereof after (c), and
perform (d) after or during (e).

27. The apparatus of claim 24, wherein the inert gas comprises argon, nitrogen, xenon, helium, krypton, or combinations of any two or more thereof.

28. The apparatus of claim 26, further comprising an exhaust system connected with the processing chamber, wherein the controller is further configured to:
cause the exhaust system to evacuate gas from the processing chamber during at least part of (e), and
perform (d) after a residual molar density of the first set of one or more process gases within the processing chamber is reduced to 10% or less of the molar density of the first set of one or more processes gases within the processing chamber during steady-state gas flow occurring during (c).

29. The apparatus of claim 24, wherein the controller is configured to cause the one or more light sources to illuminate the wafer prior to (b) to heat the wafer to a temperature within a third temperature range.

30. The apparatus of claim 24, further comprising a lift pin mechanism having a plurality of lift pins, wherein:
the lift pin mechanism is configured such that the lift pins are controllably movable between a first position and a second position relative to the pedestal,
each lift pin, in the first position, does not extend upward past the wafer support surface,
each lift pin, in the second position, extends upward past the wafer support surface, and
wherein the controller is configured to cause the lift pins of the lift pin mechanism to be in the first position during at least part of both (b) and (c).

31. The apparatus of claim 30, wherein the controller is configured to cause the lift pins of the lift pin mechanism to be in the second position during at least part of (d).

32. The apparatus of claim 30, wherein the controller is configured to:
cause the one or more light sources to illuminate the wafer prior to (b) to heat the wafer to a temperature within a third temperature range, and
cause the lift pins of the lift pin mechanism to be in the second position during at least part of the illumination of the wafer prior to (b).

33. The apparatus of claim 24, wherein the controller is configured to:
receive a command to perform a chamber cleaning operation;
cause a cleaning wafer to be placed within the processing chamber, wherein the cleaning wafer has a reflective, high-diffusivity coating on a surface thereof,
cause the one or more light sources to illuminate the surface of the cleaning wafer with the reflective, high-diffusivity finish for a first period of time; and
remove the cleaning wafer from the processing chamber after the first period of time.

34. The apparatus of claim 33, wherein the reflective, high-diffusivity coating is made of tin, tellurium, or hafnium.

35. The apparatus of claim 33, wherein the surface with the reflective, high-diffusivity coating has a surface roughness with a magnitude equivalent to one to two wavelengths of the light from the one or more light sources that illuminates the wafer.

36. The apparatus of claim 35, further comprising the cleaning wafer.
